(19) United States
(12) Patent Application Publication
(10) Pub. No.: US 2025/0172620 A1
(43) Pub. Date: May 29, 2025

(54) VOLTAGE MONITORING MODULE AND BATTERY UNIT

(71) Applicant: MEKTEC CORPORATION, Tokyo (JP)

(72) Inventors: Takuya HOSOKAWA, Tokyo (JP); Kenji KIYA, Tokyo (JP); Tomoki KANAYAMA, Tokyo (JP)

(73) Assignee: MEKTEC CORPORATION, Tokyo (JP)

(21) Appl. No.: 18/958,904

(22) Filed: Nov. 25, 2024

(30) Foreign Application Priority Data
Nov. 27, 2023 (JP) 2023-200074

(51) Int. Cl. G01R 31/3835

(52) U.S. Cl. CPC G01R 31/3835

(57) ABSTRACT

Provided is a voltage monitoring module for monitoring a voltage of a battery pack configured such that a plurality of sections, each of which includes a plurality of battery cells arranged in a first direction, is arranged in the first direction, including: a plurality of flexible printed boards, in which each of the plurality of flexible printed boards has a body portion and a plurality of branch portions; the body portion extends in the first direction; each of the plurality of branch portions is branched from the body portion; each of the plurality of branch portions is provided with a connection terminal on a tip end side; and the plurality of flexible printed boards is each arranged corresponding to each of the plurality of sections, and the connection terminal is connected to a terminal of the plurality of battery cells of the section corresponding to the flexible printed board.

### CROSS-REFERENCE TO RELATED APPLICATION

This application claims priority from Japanese Patent Application No. 2023-200074 filed with the Japan Patent Office on Nov. 27, 2023, the entire content of which is hereby incorporated by reference.

### BACKGROUND

### 1. Technical Field

The present disclosure relates to a voltage monitoring module and a battery unit.

### 2. Related Art

JP-A-2020-013766 discloses a battery assembly bus bar module including a plurality of batteries. The bus bar module includes a flexible printed board having a plurality of wires, and the flexible printed board has a main wire and a plurality of branch wires branched from the main wire. One flexible printed board corresponds to the entirety of a battery assembly, and a plurality of connection portions provided at the branch wires of such a flexible printed board are connected to all positive and negative electrodes of the plurality of batteries forming the battery assembly.

### SUMMARY

A voltage monitoring module according to the present disclosure is a voltage monitoring module for monitoring a voltage of a battery pack configured such that a plurality of sections, each of which includes a plurality of battery cells arranged in a first direction, is arranged in the first direction, including: a plurality of flexible printed boards, in which each of the plurality of flexible printed boards has a body portion and a plurality of branch portions; the body portion extends in the first direction; each of the plurality of branch portions is branched from the body portion, and is arranged at intervals in the first direction; each of the plurality of branch portions is provided with a connection terminal on a tip end side; and the plurality of flexible printed boards is each arranged corresponding to each of the plurality of sections, and the connection terminal is connected to a corresponding one of terminals of the plurality of battery cells of the section corresponding to the flexible printed board.

### BRIEF DESCRIPTION OF THE DRAWINGS

FIG. 1 is a perspective view of a battery unit according to a first embodiment;

FIG. 2 is a plan view of the battery unit according to the first embodiment;

FIG. 3 is a plan view of a voltage monitoring module according to the first embodiment;

FIGS. 4A and 4B are plan views of a battery pack according to the first embodiment, FIG. 4A showing a state upon discharge of the battery pack and FIG. 4B showing a state upon charge of the battery pack;

FIG. 5 is a perspective view showing a stretchable portion and a peripheral structure thereof according to the first embodiment;

FIGS. 6A and 6B are partially-enlarged views of a connection terminal and a peripheral structure thereof according to the first embodiment, FIG. 6A being a perspective view and FIG. 6B being a plan view;

FIGS. 7A and 7B are side views showing the stretchable portion and the peripheral structure thereof according to the first embodiment, FIG. 7A showing a state upon discharge of the battery pack and FIG. 7B showing a state upon charge of the battery pack;

FIGS. 8A and 8B are side views showing a stretchable portion and a peripheral structure thereof according to a first modification of the first embodiment, FIG. 8A showing a state upon discharge of a battery pack and FIG. 8B showing a state upon charge of the battery pack;

FIGS. 9A and 9B are side views showing a stretchable portion and a peripheral structure thereof according to a second modification of the first embodiment, FIG. 9A showing a state upon discharge of a battery pack and FIG. 9B showing a state upon charge of the battery pack;

FIG. 10 is a plan view of a battery unit according to a third modification of the first embodiment;

FIG. 11 is a plan view of a battery unit according to a fourth modification of the first embodiment;

FIG. 12 is a plan view of flexible printed boards according to a second embodiment;

FIG. 13A is a partially-enlarged plan view of branch portions and a peripheral structure thereof according to a first modification of the second embodiment, and FIG. 13B is a partially-enlarged plan view of branch portions and a peripheral structure thereof according to a second modification of the second embodiment;

FIG. 14 is a plan view of a voltage monitoring module according to a third modification of the second embodiment;

FIG. 15 is a plan view of a voltage monitoring module according to a third embodiment;

FIG. 16 is a bottom view of a flexible printed board according to the third embodiment;

FIG. 17 is a bottom view of a flexible printed board according to a first modification of the third embodiment;

FIG. 18 is a plan view of a flexible printed board according to a second modification of the third embodiment;

FIG. 19 is a perspective view of flexible printed boards according to a fourth embodiment;

FIGS. 20A and 20B are side views showing a stretchable portion and a peripheral structure thereof according to the fourth embodiment, FIG. 20A showing a state upon discharge of a battery pack and FIG. 20B showing a state upon charge of the battery pack; and

FIG. 21 is a plan view of a battery unit according to a fifth embodiment.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The battery assembly, the battery, the positive and negative electrodes, and the connection portion in JP-A-2020-013766 are each equivalent to a battery pack, a battery cell, a cell terminal, and a connection terminal in the present application. For the technique of JP-A-2020-013766, there is still room for improvement in terms of enabling a connection terminal of a voltage monitoring module to favorably follow movement of a cell terminal along with contraction or expansion of a battery cell.

One object of the present disclosure is to provide a voltage monitoring module and a battery unit configured such that a connection terminal of the voltage monitoring module can favorably follow movement of a cell terminal along with contraction or expansion of a battery cell.

The voltage monitoring module according to the present disclosure is a voltage monitoring module for monitoring a voltage of a battery pack configured such that a plurality of sections, each of which includes a plurality of battery cells arranged in a first direction, is arranged in the first direction, including: a plurality of flexible printed boards, in which each of the plurality of flexible printed boards has a body portion and a plurality of branch portions; the body portion extends in the first direction; each of the plurality of branch portions is branched from the body portion, and is arranged at intervals in the first direction; each of the plurality of branch portions is provided with a connection terminal on a tip end side; and the plurality of flexible printed boards is each arranged corresponding to each of the plurality of sections, and the connection terminal is connected to a corresponding one of terminals of the plurality of battery cells of the section corresponding to the flexible printed board.

The battery unit according to the present disclosure includes a battery pack, and a voltage monitoring module that monitors a voltage of the battery pack, in which the battery pack has a plurality of sections arranged in a first direction, and each of the plurality of sections has a plurality of battery cells arranged in the first direction; the voltage monitoring module has a plurality of flexible printed boards, in which each of the plurality of flexible printed boards has a body portion and a plurality of branch portions; the body portion extends in the first direction; each of the plurality of branch portions is branched from the body portion, and is arranged at intervals in the first direction; each of the plurality of branch portions is provided with a connection terminal on a tip end side; and the plurality of flexible printed boards is each arranged corresponding to each of the plurality of sections, and the connection terminal is connected to a corresponding one of terminals of the plurality of battery cells of the section corresponding to the flexible printed board.

According to the present disclosure, the connection terminal of the voltage monitoring module can favorably follow the movement of the cell terminal along with the contraction or expansion of the battery cell.

Hereinafter, embodiments of the present disclosure will be described with reference to the drawings. Note that in all the drawings, the same reference numerals are used to represent similar components and description thereof may be omitted as necessary.

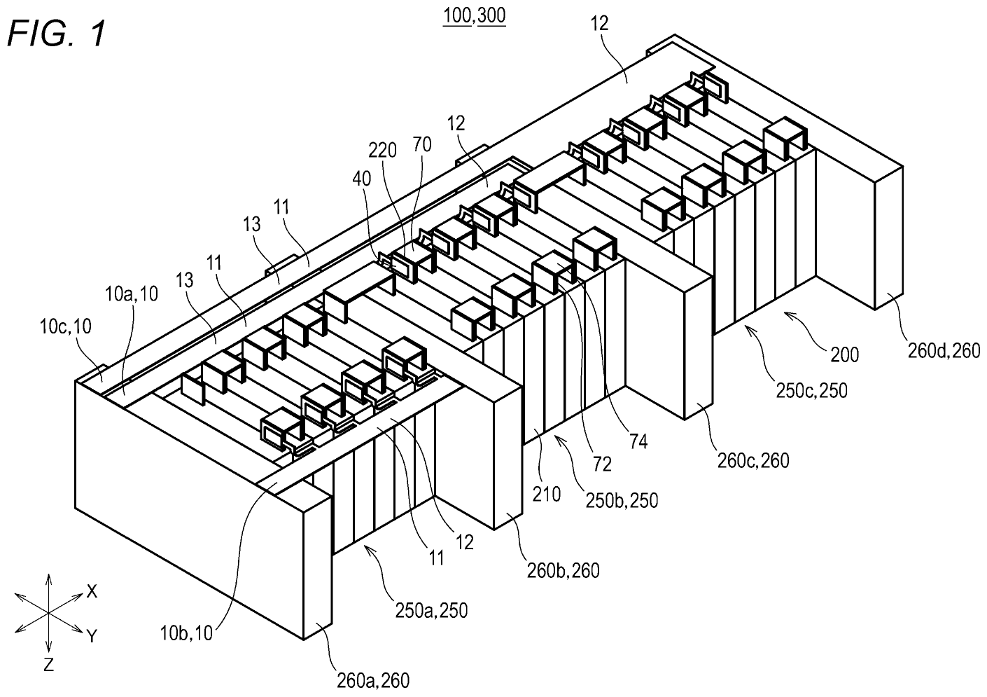

In the description below, when, e.g., a positional relationship among components of a voltage monitoring module 100 and a battery unit 300 is described, an X-direction shown in, e.g., FIG. 1 will be referred to as a first direction and a Y-direction will be referred to as a second direction. The first direction as the X-direction and the second direction as the Y-direction are the longitudinal direction and lateral direction of the voltage monitoring module 100 and the battery unit 300, respectively. Moreover, a Z-direction shown in, e.g., FIG. 1 will be referred to as a third direction. The third direction as the Z-direction is the height direction of the voltage monitoring module 100 and the battery unit 300.

The first direction may be referred to as a right-left direction, one side in the first direction may be referred to as right (rightward), and the other side may be referred to as left (leftward). Moreover, the second direction may be referred to as a front-back direction, one side in the second direction may be referred to as front (forward), and other side may be referred to as back (backward). Further, the third direction may be referred to as an up-down direction or a normal direction, one side in the third direction may be referred to as up (upper, above), and the other side may be referred to as down (lower, below). A direction perpendicular to the up-down direction may be referred to as horizontal (horizontal direction), and a direction along the up-down direction may be referred to as vertical (vertical direction).

The positional relationship among the components of the voltage monitoring module 100 and the battery unit 300 and the shapes thereof in the description below correspond to the positional relationship and the shapes upon discharge of a battery pack 200, unless otherwise specified.

### First Embodiment

First, a first embodiment will be described with reference to FIGS. 1 to 7B.

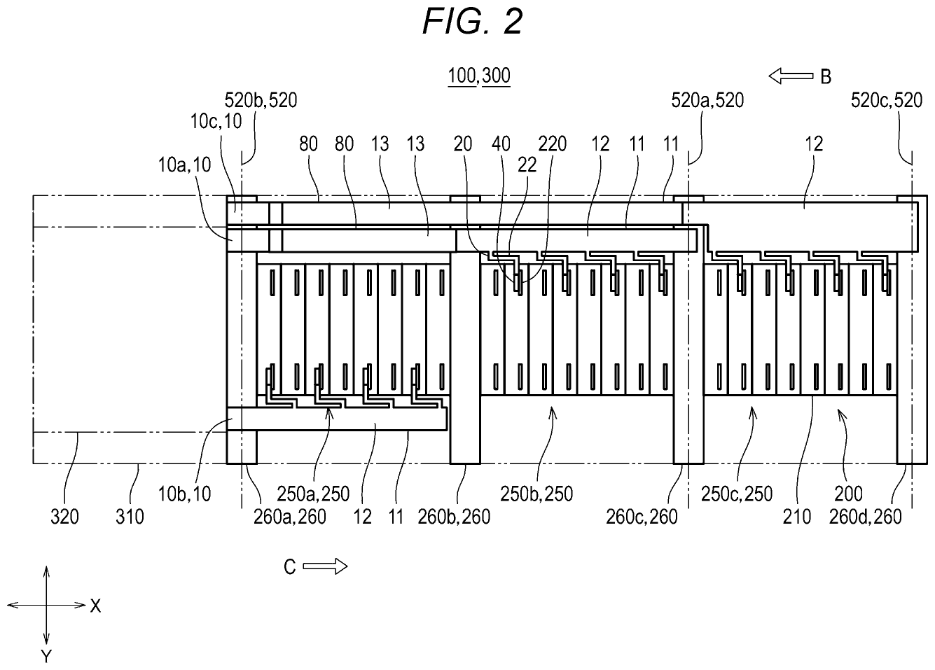

As shown in FIGS. 1 and 2, the voltage monitoring module 100 according to the present embodiment is a voltage monitoring module that monitors the state of the voltage of the battery pack 200 configured such that a plurality of sections 250, each of which has a plurality of battery cells 210 is stacked in the first direction, is arranged in the first direction. The voltage monitoring module 100 includes a plurality of flexible printed boards 10 each corresponding to one of the plurality of sections 250.

Each of the plurality of flexible printed boards 10 includes a body portion 11 extending in the first direction (in the case of the present embodiment, X-direction shown in, e.g., FIG. 1) and a plurality of branch portions 20. The plurality of branch portions 20 is branched from the body portion 11, and is provided at intervals in the first direction.

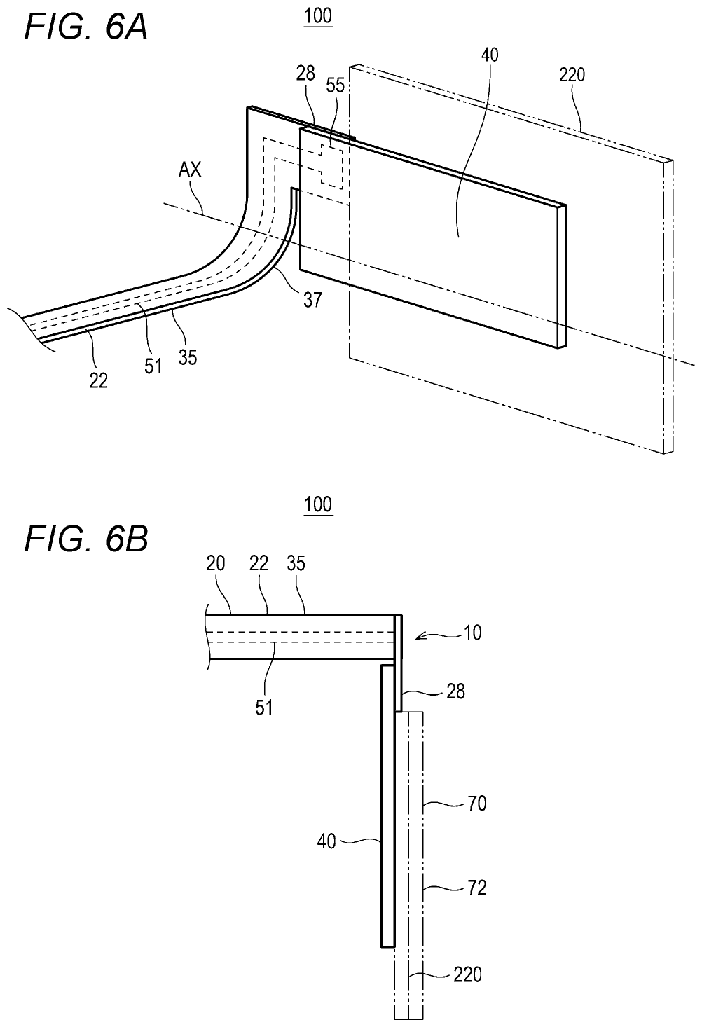

The branch portion 20 has, on the tip end side thereof, a connection terminal 55 (see FIG. 6A) to be connected to a cell terminal 220 which is a terminal of the battery cell 210. The connection terminal 55 of the branch portion 20 of the flexible printed board 10 is connected to the cell terminal 220 of the battery cell 210 of the section 250 corresponding to such a flexible printed board 10.

Note that the first direction is the longitudinal direction (right-left direction) of the flexible printed board 10 and the body portion 11.

Note that the section 250 is a section formed by the plurality of battery cells 210 continuously arranged in the first direction. In the case of the present embodiment, the battery pack 200 has the plurality of sections 250, and the plurality of battery cells 210 is linearly arranged in line in the first direction.

The plurality of flexible printed boards 10 is each provided for the plurality of sections 250 of the battery pack 200 in one-to-one correspondence. That is, the plurality of flexible printed boards 10 is arranged such that the sections 250 and the flexible printed boards 10 correspond to each other in one-to-one correspondence.

The connection terminal 55 is connected to the cell terminal 220 of the battery cell 210 of one of the plurality of sections 250 corresponding to one of the plurality of flexible printed boards 10. Meanwhile, the connection terminal 55 is not connected to the cell terminals 220 of the battery cells 210 of the other sections 250 corresponding to the flexible printed boards 10 other than the one of the plurality of flexible printed boards 10, not corresponding to the one of the plurality of flexible printed boards 10.

In other words, each connection terminal 55 of the flexible printed boards 10 is connected to the cell terminal 220 of the battery cell 210 of the corresponding section 250, and on the other hand, is not connected to the cell terminals 220 of the battery cells 210 of the sections 250 corresponding to the other flexible printed boards 10.

Moreover, one connection terminal 55 is connected to a corresponding one of the cell terminals 220 of the corresponding section 250.

The voltage monitoring module 100 is attached to the battery pack 200 such that the longitudinal direction (first direction) of the body portion 11 is along the stacking direction (arrangement direction, first direction) of the battery cells 210, and each connection terminal 55 of the voltage monitoring module 100 is connected to the cell terminal 220 of the corresponding battery cell 210.

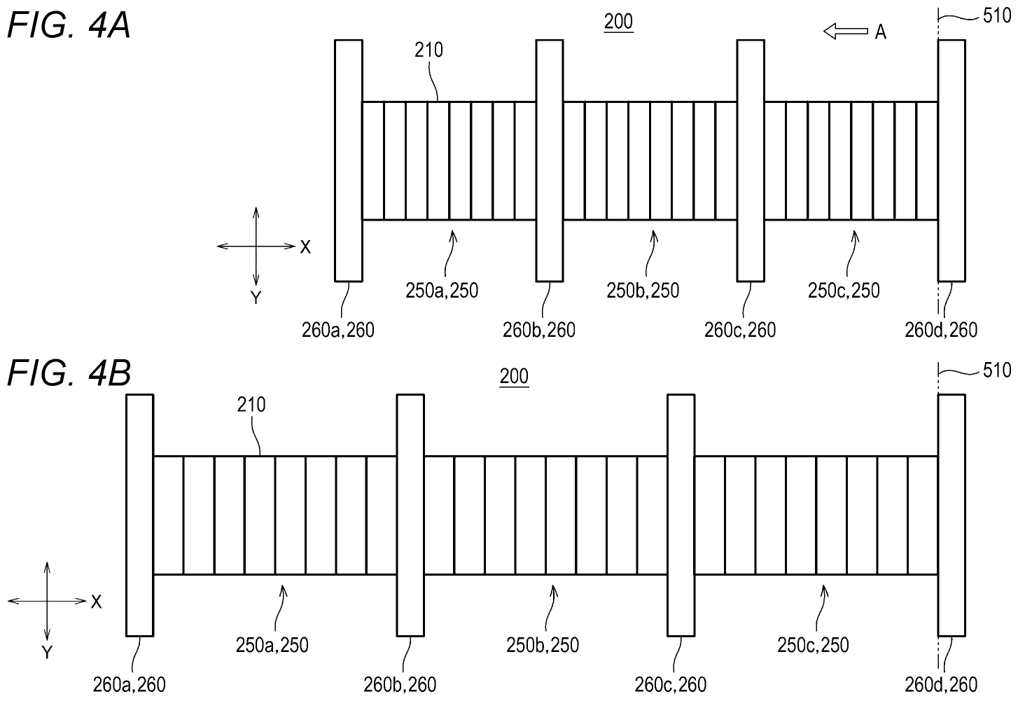

FIG. 4A shows a state upon discharge of the battery pack 200, and FIG. 4B shows a state upon charge of the battery pack 200. As shown in FIG. 4B, upon charge of the battery pack 200, each of the plurality of battery cells 210 expands in a direction (direction indicated by an arrow A in FIG. 4A) apart from a first reference position 510 (in the case of the present embodiment, the right end of the battery pack 200) in the stacking direction (first direction) with reference to the first reference position 510. As shown in FIG. 4A, upon discharge of the battery pack 200, each of the plurality of battery cells 210 contracts in a direction (direction opposite to the direction indicated by the arrow A in FIG. 4A) toward the first reference position 510 with reference to the first reference position 510.

At least part of the flexible printed board 10 in the longitudinal direction (first direction) thereof is directly or indirectly fixed to the battery pack 200. A position at which such part is fixed to the battery pack 200 in the first direction is a reference movement position (hereinafter referred to as a second reference position 520) of the connection terminal 55 (see, e.g., FIG. 2).

Upon charge of the battery pack 200, along with the expansion of the plurality of battery cells 210, each cell terminal 220 moves in the direction apart from the first reference position 510 in the first direction. Moreover, the connection terminal 55 connected to the cell terminal 220 moves in a direction (in the case of the present embodiment, direction indicated by an arrow B, C in FIG. 2) apart from the second reference position 520 so as to follow such a cell terminal 220. The movable range of the connection terminal 55 at this time is defined according to the length dimension of the branch portion 20 having the connection terminal 55. More specifically, as the length dimension of the branch portion 20 increases, the movable range of the connection terminal 55 increases.

Upon discharge of the battery pack 200, along with the contraction of the plurality of battery cells 210, each cell terminal 220 moves in the direction toward the first reference position 510 in the first direction. Moreover, the connection terminal 55 connected to the cell terminal 220 moves in a direction toward the second reference position 520 so as to follow such a cell terminal 220. The movable range of the connection terminal 55 at this time is defined according to the length dimension of the branch portion 20 having the connection terminal 55. More specifically, as the length dimension of the branch portion 20 increases, the movable range of the connection terminal 55 increases.

Of the plurality of connection terminals 55, the connection terminal 55 connected to the cell terminal 220 located farther from the second reference position 520 in the first direction has a greater movement amount (movement amount necessary to absorb a change in the position of the cell terminal 220) necessary to follow the cell terminal 220.

In reaction to the above, the voltage monitoring module 100 according to the present embodiment includes the plurality of flexible printed boards 10 each corresponding to one of the plurality of sections 250 of the battery pack 200. Moreover, the connection terminal 55 of the branch portion 20 of one of the plurality of flexible printed boards 10 is connected to the cell terminal 220 of the battery cell 210 of the section 250 corresponding to the one of the flexible printed boards 10.

With this configuration, upon the expansion or contraction of the battery cells 210, each connection terminal 55 of the flexible printed boards 10 can selectively follow the cell terminal 220 of the battery cell 210 of the corresponding section 250 among all the battery cells 210 of the battery pack 200. That is, as compared to a case where the connection terminals 55 of one flexible printed board 10 correspond to the entirety of the battery pack 200, the movement amount (movement amount necessary to absorb the change in the position of the cell terminal 220) necessary for each connection terminal 55 to follow the corresponding cell terminal 220 can be decreased. Thus, according to the present embodiment, the connection terminal 55 can favorably follow the movement of the corresponding cell terminal 220.

Further, since the movement amount necessary for each connection terminal 55 to follow the corresponding cell terminal 220 can be decreased, the length dimension of the branch portion 20 defining the movable range of each connection terminal 55 can be set smaller.

Thus, according to the present embodiment, while the connection terminal 55 is configured to be able to favorably follow the movement of the corresponding cell terminal 220, the length dimension of the branch portion 20 and therefore the entirety of the voltage monitoring module 100 can be designed more compact.

The battery unit 300 according to the present embodiment includes the voltage monitoring module 100 and the battery pack 200 of the present embodiment.

Each connection terminal 55 of the flexible printed boards 10 is connected to the cell terminal 220 of the battery pack 200 corresponding to such a connection terminal 55.

According to the present embodiment, the voltage monitoring module 100 includes, as described above, the plurality of flexible printed boards 10 each corresponding to the plurality of sections 250 of the battery pack 200. Moreover, the connection terminal 55 of the branch portion 20 of each of the plurality of flexible printed boards 10 is connected to the cell terminal 220 of the battery cell 210 of the section 250 corresponding to such a flexible printed board 10.

With this configuration, while the connection terminal 55 is configured to be able to favorably follow the movement of the corresponding cell terminal 220, the length dimension of the branch portion 20 and therefore the entirety of the voltage monitoring module 100 can be designed more compact.

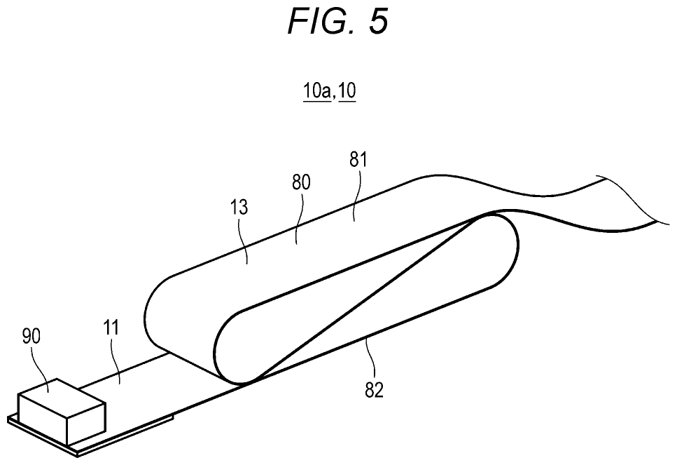

For example, a connector 90 (see FIG. 5) is attached to the flexible printed board 10. The flexible printed board 10 is connected to a measurement device that performs various types of control via the connector 90, so that the voltage can be monitored. Note that in FIGS. 1 and 2, the connector 90 is not shown.

The flexible printed board 10 is used, for example, to monitor the voltage by connection of a wire 51 to a bus bar 70 (described in detail later) connecting the plurality of battery cells 210.

The connector 90 is attached, for example, to the upper surface of an end portion (in the case of the present embodiment, left end portion) of the body portion 11 of the flexible printed board 10 opposite to the side on which the branch portion 20 is formed.

As shown in FIGS. 1 to 3, the shape of the body portion 11 of each of the plurality of flexible printed boards 10 is, for example, a substantially rectangular shape long in the first direction in plan view.

The plurality of flexible printed boards 10 is arranged in parallel with each other in the second direction, for example.

In the case of the present embodiment, the body portion(s) 11 of one or more of the flexible printed boards 10 has a corresponding-section extending portion 12 and an other-section extending portion 13. The corresponding-section extending portion 12 extends in the first direction along the section 250 corresponding to the flexible printed board 10. The other-section extending portion 13 extends in the first direction along the section(s) 250 corresponding to the other flexible printed board(s) 10. The corresponding-section extending portion 12 and the other-section extending portion 13 are provided continuously in the first direction.

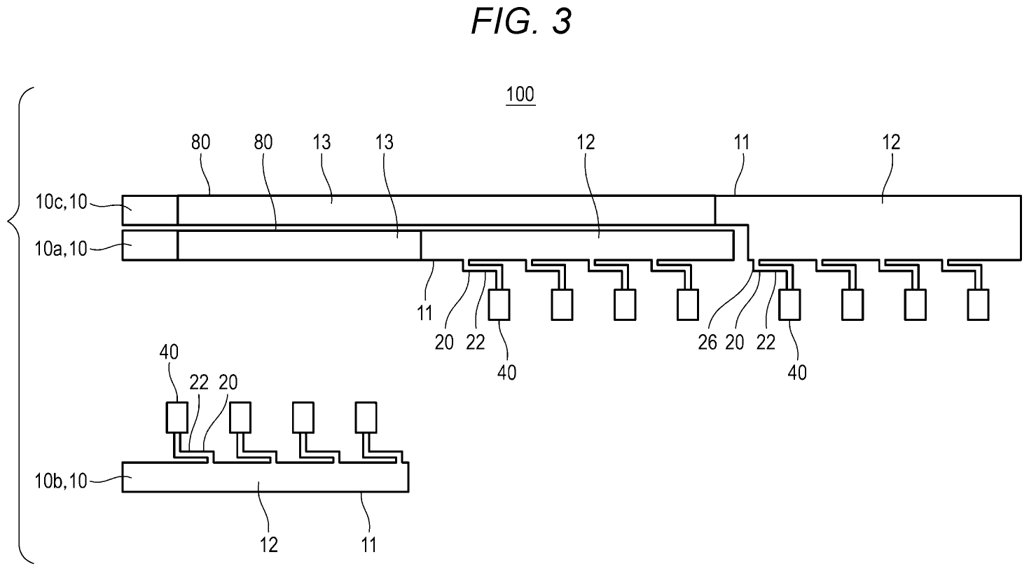

Note that as shown in FIGS. 2 and 3, in the flexible printed board 10, of the corresponding-section extending portion 12 and other-section extending portion 13, the corresponding-section extending portion 12 is formed with the plurality of branch portions 20.

According to this configuration, by adjusting, for example, the length dimension of the other-section extending portion 13, the positions of the end portions (left end portions) of the flexible printed boards 10 on the side opposite to the side on which the branch portion 20 is formed in the first direction can be aligned with each other in the second direction. Thus, the positions of attachment of the flexible printed boards 10 to the battery pack 200 and the positions of the connectors 90 attached to the flexible printed boards 10 can be aligned in the second direction.

In the case of the present embodiment, the corresponding-section extending portion 12 extends, in the first direction, from the battery cell 210 on one end side of the corresponding section 250 to the battery cell 210 on the other end side. More specifically, in the first direction, the length dimension of the corresponding-section extending portion 12 is set equal to or greater than the length dimension of the corresponding section 250. Note that in the present disclosure, the length dimension of the corresponding-section extending portion 12 may be less than the length dimension of the corresponding section 250.

The other-section extending portion 13 extends, in the first direction, from the battery cell 210 on one end side of the section 250 corresponding to the other flexible printed board(s) 10 to the battery cell 210 on the other end side. More specifically, in the first direction, the length dimension of the other-section extending portion 13 is set equal to or greater than the total of the length dimension(s) of the section(s) 250 corresponding to the other flexible printed board(s) 10. Note that in the present disclosure, the length dimension of the other-section extending portion 13 may be less than the total of the length dimension(s) of the section(s) 250 corresponding to the other flexible printed board(s) 10.

The corresponding-section extending portion 12 and the other-section extending portion 13 may be referred to as a first extending portion and a second extending portion, respectively. In this case, the first extending portion extends in the first direction along one of the plurality of sections 250 corresponding to one of the plurality of flexible printed boards 10. The second extending portion extends in the first direction along the other section(s) 250 of the plurality of sections 250 corresponding to the other flexible printed board(s) 10 of the plurality of flexible printed boards 10. In other words, the second extending portion extends in the first direction along the flexible printed board(s) 10 other than the one flexible printed board 10 corresponding to the first extending portion. The first extending portion and the second extending portion are formed continuously at the body portion 11.

The corresponding-section extending portion 12 (first extending portion) is provided on the tip end side of the flexible printed board 10 in the first direction, and the other-section extending portion 13 (second extending portion) is provided on the opposite side thereof. In the present embodiment, the second extending portion is provided on the side of the flexible printed board 10 on which the connector 90 is attached.

As one example, the body portions 11 of the plurality of flexible printed boards 10 are separated from each other. According to this configuration, the arrangement positions of the body portions 11 of the plurality of flexible printed boards 10 on the battery pack 200 can be designed with a wider degree of freedom.

Note that the phrase “separated from each other” means that the body portions 11 of the plurality of flexible printed boards 10 are separate members and these body portions 11 are not directly coupled to each other. Thus, for example, the body portions 11 may be indirectly coupled to each other via other members (e.g., later-described partition plates 260).

More specifically, in the case of the present embodiment, the battery pack 200 has three sections 250 (first section 250a, second section 250b, and third section 250c in this order from the left side). The voltage monitoring module 100 includes three flexible printed boards 10 (first flexible printed board 10a, second flexible printed board 10b, and third flexible printed board 10c) each corresponding to these three sections 250. The body portions 11 of the first flexible printed board 10a, the second flexible printed board 10b, and the third flexible printed board 10c are separated from each other.

The first flexible printed board 10a corresponds to the second section 250b, and has the corresponding-section extending portion 12 extending in the first direction along the second section 250b and the other-section extending portion 13 extending in the first direction along the first section 250a. A left end portion of the first flexible printed board 10a is formed by a left end portion of the other-section extending portion 13 of the first flexible printed board 10a, and a right end portion of the first flexible printed board 10a is formed by a right end portion of the corresponding-section extending portion 12 of the first flexible printed board 10a.

The second flexible printed board 10b corresponds to the first section 250a, and has the corresponding-section extending portion 12 extending in the first direction along the first section 250a, but has no other-section extending portion 13. A left end portion of the second flexible printed board 10b is formed by a left end portion of the corresponding-section extending portion 12 of the second flexible printed board 10b, and a right end portion of the second flexible printed board 10b is formed by a right end portion of the corresponding-section extending portion 12 of the second flexible printed board 10b.

The third flexible printed board 10c corresponds to the third section 250c, and has the corresponding-section extending portion 12 extending in the first direction along the third section 250c and the other-section extending portion 13 extending in the first direction along the first section 250a and the second section 250b. A left end portion of the third flexible printed board 10c is formed by a left end portion of the other-section extending portion 13 of the third flexible printed board 10c, and a right end portion of the third flexible printed board 10c is formed by a right end portion of the corresponding-section extending portion 12 of the third flexible printed board 10c.

In the case of the present embodiment, the plurality of flexible printed boards 10 includes the third flexible printed board 10c, the first flexible printed board 10a, and the second flexible printed board 10b arranged in this order from the back side to the front side in the second direction.

More specifically, with reference to the battery pack 200, the second flexible printed board 10b is disposed on one side (in the case of the present embodiment, front side) in the second direction, and the third flexible printed board 10c and the first flexible printed board 10a are arranged on the other side (in the case of the present embodiment, back side) in the second direction. The first flexible printed board 10a is disposed between the third flexible printed board 10c and the battery pack 200 in the second direction.

The plurality of branch portions 20 of the third flexible printed board 10c is formed at the front edge of the corresponding-section extending portion 12 of the third flexible printed board 10c. The connection terminals 55 of the plurality of branch portions 20 of the third flexible printed board 10c are connected to the cell terminals 220 of the battery cells 210 of the third section 250c.

Similarly, the plurality of branch portions 20 of the first flexible printed board 10a is formed at the front edge of the corresponding-section extending portion 12 of the first flexible printed board 10a. The connection terminals 55 of the plurality of branch portions 20 of the first flexible printed board 10a are connected to the cell terminals 220 of the battery cells 210 of the second section 250b.

The plurality of branch portions 20 of the second flexible printed board 10b is formed at the back edge of the corresponding-section extending portion 12 of the second flexible printed board 10b. The connection terminals 55 of the plurality of branch portions 20 of the second flexible printed board 10b are connected to the cell terminals 220 of the battery cells 210 of the first section 250a.

In the case of the present embodiment, for example, the width of the corresponding-section extending portion(s) 12 of one or more of the flexible printed boards 10 is formed greater than the width of the other-section extending portions 13 of these flexible printed boards 10. That is, the length dimension of the corresponding-section extending portion 12 in the second direction is greater than the length dimension of the other-section extending portion 13 in the second direction.

According to this configuration, even in a case where one or more of the flexible printed boards 10 are arranged farther from the battery pack 200 in the second direction than the other flexible printed board(s) 10, the branch portions 20 of the corresponding-section extending portions 12 can be easily arranged in the vicinity of the battery pack 200. Thus, the connection terminals 55 of these flexible printed boards 10 can be favorably connected to the corresponding cell terminals 220.

More specifically, for example, in the example shown in FIG. 2, one flexible printed board 10 (third flexible printed board 10c) and the other flexible printed board 10 (first flexible printed board 10a) are arranged apart from each other in the second direction. In this case, the width dimension of the corresponding-section extending portion 12 of the third flexible printed board 10c is preferably set to a dimension greater than a separation distance between the third flexible printed board 10c and the first flexible printed board 10a. More preferably, the width dimension of the corresponding-section extending portion 12 of the third flexible printed board 10c is substantially equal to the total of the width dimension of the other-section extending portion 13 of the third flexible printed board 10c, the separation distance between the third flexible printed board 10c and the first flexible printed board 10a and the width dimension of the corresponding-section extending portion 12 of the first flexible printed board 10a. According to this configuration, in the second direction, the position of the corresponding-section extending portion 12 of the third flexible printed board 10c and the position of the corresponding-section extending portion 12 of the first flexible printed board 10a can be aligned with each other.

In the case of the present embodiment, the width of the corresponding-section extending portion 12 of the third flexible printed board 10c disposed farthest from the battery pack 200 in the second direction among the plurality of flexible printed boards 10 is greater than the width of the first flexible printed board 10a, as one example. More specifically, the width dimension (length dimension in the second direction) of the corresponding-section extending portion 12 of the third flexible printed board 10c is, for example, about twice the width dimension of the first flexible printed board 10a.

In the present embodiment, as shown in FIGS. 1 and 2, the length dimension (dimension in the first direction) of the flexible printed board 10 increases in the order of the second flexible printed board 10b, the first flexible printed board 10a, and the third flexible printed board 10c.

The left ends of the first flexible printed board 10a, the second flexible printed board 10b, and the third flexible printed board 10c are arranged at the same position in the first direction. On the other hand, the right end of the second flexible printed board 10b ends in the vicinity of the right end of the first section 250a, the right end of the first flexible printed board 10a ends in the vicinity of the right end of the second section 250b, and the right end of the third flexible printed board 10c ends in the vicinity of the right end of the third section 250c.

As described above, in the case of the present embodiment, the width of the corresponding-section extending portion 12 of the third flexible printed board 10c is formed to be greater than the width of the other-section extending portion 13 of the third flexible printed board 10c. That is, the length dimension of the corresponding-section extending portion 12 of the third flexible printed board 10c in the second direction is greater than the length dimension of the other-section extending portion 13 of the third flexible printed board 10c.

On the other hand, the width of the corresponding-section extending portion 12 of the first flexible printed board 10a is set to a width dimension equal to the width of the other-section extending portion 13 of the first flexible printed board 10a. That is, the width dimension of the body portion 11 of the first flexible printed board 10a is constant regardless of the position in the longitudinal direction (first direction).

Similarly, the width dimension of the body portion 11 of the second flexible printed board 10b including the corresponding-section extending portion 12 is constant regardless of the position in the longitudinal direction (first direction).

The width of the other-section extending portion 13 of the third flexible printed board 10c, the width of the body portion 11 of the first flexible printed board 10a, and the width of the body portion 11 of the second flexible printed board 10b are set to the same width dimension, for example.

As shown in FIG. 2, the second reference position 520 of the flexible printed board 10 corresponding to the section 250 located farther from the first reference position 510 in the first direction is set to a position farther from the first reference position 510.

According to this configuration, in each flexible printed board 10, the movement amount necessary for the connection terminal 55 to follow the corresponding cell terminal 220 can be decreased.

More specifically, in the case of the present embodiment, both end portions of the body portion 11 of the first flexible printed board 10a are fixed to the battery pack 200 (for example, via later-described partition plates 260). The position at which a first reference position 510-side end portion (in the case of the present embodiment, right end portion) of the body portion 11 of the first flexible printed board 10a is fixed to the battery pack 200 in the first direction is the second reference position 520 (hereinafter referred to as a second reference position 520a) of the first flexible printed board 10a. The second reference position 520a of the first flexible printed board 10a is located in the vicinity of the battery cell 210 located closest to the first reference position 510 side in the second section 250b.

Similarly, both end portions of the body portion 11 of the third flexible printed board 10c are fixed to the battery pack 200. The position at which the first reference position 510-side end portion (in the case of the present embodiment, right end portion) of the body portion 11 of the third flexible printed board 10c is fixed to the battery pack 200 in the first direction is the second reference position 520 (hereinafter referred to as a second reference position 520c) of the third flexible printed board 10c. The second reference position 520c of the third flexible printed board 10c is located in the vicinity of the battery cell 210 located closest to the first reference position 510 side in the third section 250c.

On the other hand, an end portion (in the case of the present embodiment, left end portion) of the body portion 11 of the second flexible printed board 10b opposite to the first reference position 510 side is fixed to the battery pack 200, and the first reference position 510-side end portion (in the case of the present embodiment, right end portion) is not fixed to the battery pack 200. The position at which the end portion of the second flexible printed board 10b opposite to the first reference position 510 side is fixed to the battery pack 200 in the first direction is the second reference position 520 (hereinafter referred to as a second reference position 520b) of the second flexible printed board 10b. The second reference position 520b of the second flexible printed board 10b is located in the vicinity of the battery cell 210 located farthest from the first reference position 510 in the first section 250a.

Further, in the case of the present embodiment, among the flexible printed boards 10, a separation distance in the first direction between the second reference position 520 and the cell terminal 220 located farthest from the second reference position 520 of the corresponding section 250 is set to the substantially same distance.

According to this configuration, the maximum value of the movement amount necessary for the connection terminal 55 to follow the corresponding cell terminal 220 can be made substantially the same among the flexible printed boards 10. Thus, the movement of the cell terminal 220 due to the expansion and contraction of the battery cell 210 can be distributed and absorbed substantially equally in each flexible printed board 10.

Further, as compared to a case where one flexible printed board 10 corresponds to the entirety of the battery pack 200, the maximum value of the movement amount necessary for the connection terminal 55 to follow the corresponding cell terminal 220 can be further decreased. Thus, while the connection terminal 55 is configured to be able to favorably follow the movement of the corresponding cell terminal 220 in each flexible printed board 10, the length dimension of the branch portion 20 and therefore the entirety of the voltage monitoring module 100 can be designed more compact.

Note that in the present disclosure, the flexible printed boards 10 are not necessarily arranged on both sides (in the case of the present embodiment, front and back sides) of the battery pack 200 in the second direction. For example, the plurality of flexible printed boards 10 may be selectively arranged only on one side or the other side (front or back side) of the battery pack 200 in the second direction.

Moreover, in the present disclosure, the flexible printed board 10 disposed on one side of the battery pack 200 in the second direction and the flexible printed board 10 disposed on the other side in the second direction may be replaced with each other. In this case, the shape and orientation of the flexible printed board 10 may be set as necessary such that the front or back edge of the flexible printed board 10 on the side on which the branch portion 20 is formed is on the battery pack 200 side.

The other-section extending portion(s) 13 of the body portion(s) 11 of one or more of the plurality of flexible printed boards 10 has, for example, a stretchable portion 80 (see FIG. 5) extendable and contractable in the first direction. Note that in FIG. 1, the stretchable portion 80 is not shown for the sake of convenience and the entirety of the other-section extending portion 13 is shown in a flat shape.

According to this configuration, by extension and contraction of the stretchable portion 80, the other-section extending portion 13 can follow the expansion and contraction of the battery cells 210 in the section(s) 250 corresponding to the other flexible printed board(s) 10 (can absorb the expansion and contraction of the battery cells 210).

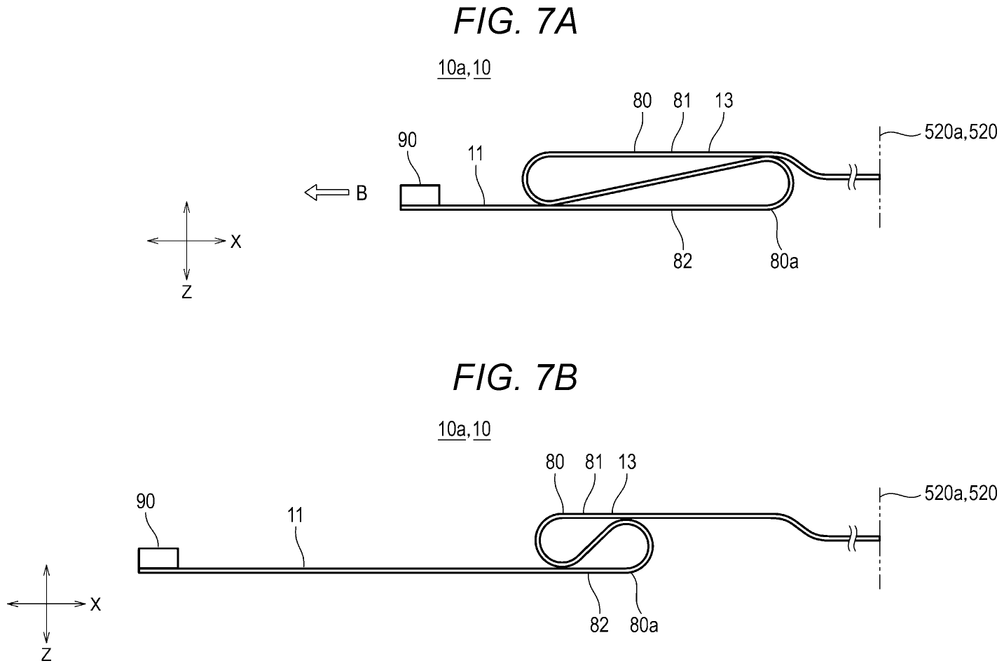

As shown in FIGS. 5, 7A, and 7B, in the case of the present embodiment, the body portion 11 is folded back, and parts of the body portion 11 overlap with each other at the stretchable portion 80 of the other-section extending portion 13.

According to this configuration, the maximum extension range of the stretchable portion 80 and the minimum contraction range of the stretchable portion 80 can be favorably ensured.

Here, the phrase “the parts of the body portion 11 overlap with each other” means that parts of the body portion 11 overlap with each other in a direction parallel with the normal direction (third direction) to a portion of the body portion 11 extending flat.

More specifically, for example, at the stretchable portion 80, part of the body portion 11 is folded so as to go back and forth one and a half times or more in the first direction. The part of the body portion 11 meanders in the normal direction of the body portion 11 (the third direction).

In other words, part of the body portion 11 is folded back two or more times along the first direction so as to form a bellow shape in the third direction when viewed along the second direction.

According to this configuration, the maximum extension range of the stretchable portion 80 can be favorably ensured.

More specifically, in the case of the present embodiment, each of the other-section extending portion 13 of the first flexible printed board 10a and the other-section extending portion 13 of the third flexible printed board 10c has the stretchable portion 80.

As shown in FIGS. 5 and 7A, in the case of the present embodiment, at the stretchable portion 80 of each of the first flexible printed board 10a and the third flexible printed board 10c, the other-section extending portion 13 is folded so as to go back and forth approximately one and a half times in the first direction. Such part of the other-section extending portion 13 is curved in such a shape that a substantially S-shape lies on its side as viewed in the second direction. More specifically, part of the other-section extending portion 13 is folded back while being curved from a second reference position 520 side (hereinafter merely referred to as the right side) to the side (hereinafter merely referred to as the left side) opposite to the second reference position 520 in the first direction, and thereafter, is further folded back while being curved from the left side to the right side in the first direction. A portion (hereinafter referred to as a first portion 81) of the stretchable portion 80 folded back from the left side to the right side is stacked on a portion (hereinafter referred to as a second portion 82) folded back from the right side to the left side. Part of the flat surface of the first portion 81 and part of the flat surface of the second portion 82 are in a state of facing each other in the up-down direction (third direction).

As shown in FIG. 2, the stretchable portion 80 of the third flexible printed board 10c extends over the substantially entirety of each of the first section 250a and the second section 250b in the first direction.

The stretchable portion 80 of the first flexible printed board 10a extends over the substantially entirety of the first section 250a in the first direction.

Note that in FIGS. 5, 7A, and 7B, the stretchable portion 80 of the first flexible printed board 10a is shown, but the stretchable portion 80 of the third flexible printed board 10c is not shown.

Note that in the present disclosure, the shape of the stretchable portion 80 is not limited to that of the above-described example, and for example, the part of the body portion 11 may be folded go back and forth in the first direction approximately two and a half times or more, for example, three and a half times.

In the case of the present embodiment, the stretchable portion 80 (body portion 11) is in an extended state before being attached to the battery pack 200, and is in a state of being folded back (contracted state) by being attached and fixed to the battery pack 200. Note that in the present disclosure, even in the state before being attached to the battery pack 200, the stretchable portion 80 (body portion 11) may be in the state of being folded back (contracted state) (e.g., by being held by a later-described case 65).

In the case of the present embodiment, upon charge of the battery pack 200, the stretchable portion 80 extends in the direction apart from the second reference position 520 along with the expansion of the battery cells 210 of the section(s) 250 corresponding to the other flexible printed board(s) 10. More specifically, as the battery cells 210 expand, the folding start point 80a of the stretchable portion 80 also moves in the same direction. At this time, part of the stretchable portion 80 deforms from the folded shape to an extending substantially flat shape (see FIG. 7B). Then, along with the movement of the connection terminals 55, the length dimension of the extending substantially flat portion of the stretchable portion 80 gradually increases, and the length dimension of the folded portion gradually decreases. In this manner, the stretchable portion 80 can extend in the direction apart from the second reference position 520.

Upon discharge of the battery pack 200, the stretchable portion 80 contracts in the direction toward the second reference position 520 along with the contraction of the battery cells 210 of the section(s) 250 corresponding to the other flexible printed board(s) 10. More specifically, as the battery cells 210 contract, the folding start point 80a of the stretchable portion 80 also moves in the same direction. At this time, part of the stretchable portion 80 deforms from the extending substantially flat shape to the folded shape (see FIG. 7A). Then, along with the movement of the connection terminals 55, the length dimension of the extending substantially flat portion of the stretchable portion 80 gradually decreases, and the length dimension of the folded portion gradually increases. In this manner, the stretchable portion 80 can contract in the direction toward the second reference position 520.

Note that in the present disclosure, the “folding start point 80a” means the standing start position of the other-section extending portion 13 from the extending flat state.

As shown in FIGS. 2 and 3, the branch portion 20 includes a first-direction extending portion 22 extending in the first direction, for example.

Each of the plurality of branch portions 20 has, for example, a protruding portion 26, the first-direction extending portion 22, a tip end protruding portion 28, and the connection terminal 55. The protruding portion 26 protrudes from the body portion 11 in the second direction (Y-direction) perpendicular to both the normal direction and first direction (X-direction) of the body portion 11. The first-direction extending portion 22 extends in the first direction from a tip end portion of the protruding portion 26. The tip end protruding portion 28 protrudes in the second direction from a tip end portion (end portion opposite to the protruding portion 26 side) of the first-direction extending portion 22. As shown in FIG. 6A, the tip end protruding portion 28 has the connection terminal 55. Note that in the figures other than the FIG. 6A, the connection terminal 55 is not shown as necessary.

Each of the first-direction extending portion 22, the protruding portion 26, and the tip end protruding portion 28 extends linearly in plan view.

In the case of the present embodiment, upon charge of the battery pack 200, when each connection terminal 55 moves in the direction apart from the first reference position 510 in the first direction so as to follow the corresponding cell terminal 220, the tip end protruding portion 28 of the branch portion 20 is dragged by the cell terminal 220 and also moves in the direction apart from the second reference position 520.

Note that when the movement amount (movement distance of the cell terminal 220 in the first direction) of the cell terminal 220 is less than the length dimension of the first-direction extending portion 22, part of the first-direction extending portion 22 bends in an upwardly-raised arc shape. Accordingly, the connection terminal 55 can follow the corresponding cell terminal 220.

On the other hand, when the movement amount of the cell terminal 220 is greater than the length dimension of the first-direction extending portion 22, part of the first-direction extending portion 22 deforms to a shape folded back while being curved from the second reference position 520 side to the side opposite to the second reference position 520 in the first direction. More specifically, flat surfaces of part of the first-direction extending portion 22 are in a state of facing each other in the up-down direction. As the tip end protruding portion 28 moves in the direction apart from the second reference position 520, the folding start point of the first-direction extending portion 22 also moves in the same direction. At this time, the length dimension of the lower portion of the first-direction extending portion 22 gradually decreases, and the length dimension of the upper portion gradually increases. Accordingly, the connection terminal 55 can follow the corresponding cell terminal 220.

Upon discharge of the battery pack 200, when each connection terminal 55 moves in the direction toward the first reference position 510 in the first direction so as to follow the corresponding cell terminal 220, the tip end protruding portion 28 of the branch portion 20 is dragged by the cell terminal 220 and also moves in the direction toward the second reference position 520.

At this time, when part of the first-direction extending portion 22 bends in the upwardly-raised arc shape upon charge of the battery pack 200, such a bent portion deforms (returns) to the extending substantially flat shape. Accordingly, the connection terminal 55 can follow the corresponding cell terminal 220.

On the other hand, when part of the first-direction extending portion 22 deforms, upon charge of the battery pack 200, to the shape folded back while being curved from the second reference position 520 side to the side opposite to the second reference position 520 in the first direction, as the tip end protruding portion 28 moves in the direction toward the second reference position 520, the folding start point of the first-direction extending portion 22 also moves in the same direction. At this time, the length dimension of the lower portion of the first-direction extending portion 22 gradually increases, and the length dimension of the upper portion gradually decreases. Thus, the part of the first-direction extending portion 22 deforms (returns) to the extending substantially flat shape from the folded shape. Thus, the connection terminal 55 can follow the corresponding cell terminal 220.

The branch portion 20 has, for example, a first portion 35 bent about an axis AX (see FIG. 6A) crossing both the normal direction and first direction of the body portion 11 and extending in the first direction and a second portion 37 having the connection terminal 55 and standing from the first portion 35. Note that in FIG. 6A, the axis AX is indicated by a dash-dot-dot line. In the case of the present embodiment, the axial direction of the axis AX is the second direction perpendicular to both the normal direction (up-down direction) and first direction of the body portion 11. Note that in the present disclosure, the axis AX is only required to cross at least both the normal direction and first direction of the body portion 11, and is not necessarily perpendicular to both the normal direction and first direction of the body portion 11.

Part (second portion 37) of the branch portion 20 stands in advance, and such a standing portion has the connection terminal 55. Thus, upon charge of the battery pack 200, the first-direction extending portion 22 can smoothly deform to the shape folded back from the second reference position 520 side to the side opposite to the second reference position 520 in the first direction. That is, the connection terminal 55 can smoothly move in the direction apart from the second reference position 520 so as to follow the movement of the cell terminal 220.

More specifically, in the case of the present embodiment, a tip end portion of the first-direction extending portion 22 and the tip end protruding portion 28 form the second portion 37, and a portion of the tip end portion of the first-direction extending portion 22 other than the second portion 37 forms the first portion 35.

In the case of the present embodiment, each of the first-direction extending portions 22 of the plurality of flexible printed boards 10 is set to have the same length dimension. That is, the movable range of each of the connection terminals 55 of the first flexible printed board 10a, the second flexible printed board 10b, and the third flexible printed board 10c is set to the same range.

Even in this case, according to the voltage monitoring module 100 of the present embodiment described above, the movement amount necessary for each connection terminal 55 to follow the corresponding cell terminal 220 can be further decreased. Thus, while the connection terminal 55 can be configured to be able to favorably follow the movement of the corresponding cell terminal 220, the length dimension of the branch portion 20 and furthermore the entirety of the voltage monitoring module 100 can be designed more compact.

More specifically, the branch portions 20 of the first flexible printed board 10a and the third flexible printed board 10c are set to the same shape and the same dimensions. The branch portions 20 of the second flexible printed board 10b are formed in a shape symmetrical to the branch portions 20 of the third flexible printed board 10c and the first flexible printed board 10a in the right-left direction, and are arranged symmetrical to these branch portions 20 in the front-back direction.

Note that in the present disclosure, the branch portions 20 of the plurality of flexible printed boards 10 may be set to have different shapes and dimensions.

The plurality of wires 51 of the flexible printed board 10 extends from the inside of the body portion 11 to the tip end protruding portions 28 of the branch portions 20. For example, one wire 51 is disposed for each branch portion 20. One connection terminal 55 is formed at each tip end protruding portion 28, and the tip end of each wire 51 is connected to the corresponding connection terminal 55. The connection terminal 55 is exposed, for example, on the surface of the tip end protruding portion 28.

As shown in FIG. 1, the voltage monitoring module 100 includes, for example, the flexible printed boards 10 and a plurality of bus bars 70, and the plurality of battery cells 210 is connected in series via these bus bars 70. Note that in the present disclosure, the bus bar 70 may connect some of the plurality of battery cells 210 in parallel, for example.

The bus bar 70 is disposed on the cell terminal 220, and is connected (e.g., laser-welded) to such a cell terminal 220. Note that in FIG. 2, the bus bar 70 is not shown.

The bus bar 70 is formed in such a manner that a flat plate-shaped metal member is bent multiple times. The shape of the bus bar 70 is not particularly limited, and as one example, is a substantially inverted U-shape as viewed in the second direction.

More specifically, the bus bar 70 includes a pair of right and left outer leg portions 72 and a main portion 74 bridged between the pair of right and left outer leg portions 72.

The pair of right and left outer leg portions 72 stands in the vertical direction, and each plate surface thereof is perpendicular to the first direction. As shown in FIGS. 1 and 6B, each outer leg portion 72 is disposed on the cell terminal 220, and is connected (e.g., laser-welded) to such a cell terminal 220. More specifically, the left outer leg portion 72 is connected to the cell terminal 220 of the left one of two battery cells 210 arranged adjacent to each other in the first direction, and the right outer leg portion 72 is connected to the cell terminal 220 of the right battery cell 210. Note that in FIG. 6B, one of the pair of right and left outer leg portions 72 is indicated by a dash-dot-dot line.

The main portion 74 is formed, for example, in a substantially rectangular flat plate shape long in the first direction in plan view, and the plate surface thereof is oriented horizontally.

Note that in the present disclosure, the shape of the bus bar 70 is not limited to that of the example shown in FIG. 1 and may be, for example, a substantially M-shape as viewed in the second direction.

As shown in FIG. 2, in the case of the present embodiment, the battery unit 300 includes, for example, a housing 310 that houses the battery pack 200 and a buffer 320 that biases the plurality of battery cells 210 toward the first reference position 510 side. Note that in FIG. 2, the housing 310 and the buffer 320 are indicated by dash-dot-dot lines.

As shown in FIG. 2, the entirety of the battery pack 200 is housed in the housing 310.

Note that in the present disclosure, the battery unit 300 may include a thermistor (not shown) that detects the temperature of the battery pack 200 and a wire (not shown) connecting the thermistor and a measurement device that performs various types of control.

The buffer 320 biases the plurality of battery cells 210 toward the first reference position 510 side. The buffer 320 is extendable and contractable in the first direction along with the expansion and contraction of the battery cells 210. More specifically, upon charge of the battery pack 200, the buffer 320 is pressed by the battery cells 210, and is compressed in the first direction against the elastic restoring force thereof. Upon discharge of the battery pack 200, the buffer 320 is elastically restored and extends in the first direction. Thus, even when the battery cells 210 repeatedly expand and contract, the buffer 320 can suppress displacement of the right end (first reference position 510) of the battery pack 200 relative to the housing 310.

The buffer 320 is not particularly limited, and in the case of the present embodiment, a cushion member may be used as one example.

Note that in the present disclosure, the buffer 320 may be, e.g., a spring member that biases the battery cells 210 toward the first reference position 510 side.

Each of the plurality of battery cells 210 is a secondary battery.

As shown in FIGS. 1 and 2, each of the plurality of battery cells 210 is formed in a rectangular flat plate shape as viewed in the second direction. The plurality of battery cells 210 is set to have the same shape and the same dimensions.

Each of the plurality of battery cells 210 has, for example, a pair of front and back cell terminals 220. Each of the pair of front and back cell terminals 220 stands upward from the upper end surface of the corresponding battery cell 210, for example.

The shape of the cell terminal 220 is not particularly limited. As one example, the cell terminal 220 is formed in a substantially rectangular flat plate shape as viewed in the second direction, and the plate surface thereof is perpendicular to the first direction. One cell terminal 220 is connected to each connection terminal 55.

As shown in FIG. 6A, in the case of the present embodiment, the connection terminal 55 is connected to the cell terminal 220 in a posture perpendicular to the body portion 11. Note that in FIGS. 6A and 6B, the cell terminal 220 is indicated by a dash-dot-dot line.

With this configuration, in the first direction, the connection terminal 55 can smoothly move in the direction apart from the first reference position 510 so as to follow the movement of the cell terminal 220.

In the case of the present embodiment, as shown in FIG. 6B, the connection terminal 55 is connected to the cell terminal 220 via a welding plate 40, for example.

The shape of the welding plate 40 is not particularly limited. As one example, the welding plate 40 is formed in a substantially rectangular flat plate shape, and the plate surface of the welding plate 40 is a surface perpendicular to the first direction.

The welding plate 40 is disposed on one surface of the cell terminal 220, and by welding, is joined to the one surface of the cell terminal 220. A branch portion 20-side end portion of the welding plate 40 protrudes from the cell terminal 220 to the branch portion 20 side. The tip end protruding portion 28 and therefore the connection terminal 55 of the branch portion 20 are connected to the portion of the welding plate 40 protruding from the cell terminal 220. More specifically, a tip end portion of the tip end protruding portion 28 is disposed on a cell terminal 220-side surface of the welding plate 40, and is soldered to such a cell terminal 220-side surface, for example.

In this manner, the connection terminal 55 is electrically connected to the cell terminal 220 in the posture perpendicular to the body portion 11.

Note that in the present disclosure, a method for connecting the connection terminal 55 to the cell terminal 220 is not limited to this example, and the connection terminal 55 may be directly connected to the cell terminal 220 without the welding plate 40, for example.

The outer leg portion 72 of the bus bar 70 described above is disposed on the surface of the cell terminal 220 opposite to the welding plate 40 side, and is joined to such an opposite surface.

Note that in the present disclosure, the bus bars 70 are not necessarily connected to all the cell terminals 220. In the case of the present embodiment, no bus bars 70 are connected to the cell terminal 220 located on the leftmost side and the cell terminal 220 located on the rightmost side among the plurality of cell terminals 220.

The battery unit 300 includes, for example, the plurality of partition plates 260. The battery pack 200 is partitioned into the plurality of sections 250 by the plurality of partition plates 260. The plurality of partition plates 260 is arranged with the plurality of battery cells 210 interposed therebetween in the first direction (stacking direction of the battery cells 210). In the case of the present embodiment, the battery pack 200 includes four partition plates 260 (first partition plate 260a, second partition plate 260b, third partition plate 260c, and fourth partition plate 260d in this order from the left side), and the plurality of battery cells 210 is partitioned into the three sections 250 (first section 250a, second section 250b, and third section 250c) by these four partition plates 260.

Each of the sections 250 includes the same number (e.g., eight) of battery cells 210, for example. Note that in the present disclosure, the number of battery cells 210 may be different among the sections 250.

The plate surface of each partition plate 260 is along the plate surface of the adjacent battery cell 210. In each section 250, the plate surfaces of adjacent ones of the battery cells 210 are in surface contact with each other.

In the case of the present embodiment, the fourth partition plate 260d disposed closest to the first reference position 510 side among the four partition plates 260 does not displace relative to the battery pack 200 upon the expansion and contraction of the battery cells 210. On the other hand, the other partition plates 260 (first partition plate 260a to third partition plate 260c) move in the direction apart from the first reference position 510 along with the expansion of the battery cells 210, and move in the direction toward the first reference position 510 along with the contraction of the battery cells 210.

As shown in FIG. 2, the width dimension (dimension in the second direction) of the plurality of partition plates 260 is greater than the width dimension of each of the battery cells 210, and the plurality of partition plates 260 projects to both sides in the second direction with respect to each of the battery cells 210.

In the case of the present embodiment, the voltage monitoring module 100 is bridged between the plurality of partition plates 260, and is disposed above the battery pack 200, as one example.

More specifically, a left end portion of the body portion 11 of each of the first flexible printed board 10a, the second flexible printed board 10b, and the third flexible printed board 10c is fixed to a back end portion of the upper end surface of the first partition plate 260a.

A right end portion of the body portion 11 of the first flexible printed board 10a is fixed to a back end portion of the upper end surface of the third partition plate 260c. That is, the first flexible printed board 10a extends in the first direction from the first partition plate 260a to the third partition plate 260c over the second partition plate 260b along the first section 250a and the second section 250b.

A right end portion of the body portion 11 of the second flexible printed board 10b ends on the near side (left side) with respect to the second partition plate 260b, and is not fixed to the second partition plate 260b.

A right end portion of the body portion 11 of the third flexible printed board 10c is fixed to a back end portion of the upper end surface of the fourth partition plate 260d. That is, the third flexible printed board 10c extends in the first direction from the first partition plate 260a to the fourth partition plate 260d over the second partition plate 260b and the third partition plate 260c along the first section 250a to the third section 250c.

In this manner, the voltage monitoring module 100 is bridged between the plurality of partition plates 260, and is disposed above the battery pack 200. In this state, the voltage monitoring module 100 is attached such that the longitudinal direction (first direction) of the body portion 11 is along the stacking direction of the battery cells 210, as described above.

Note that in the present disclosure, the body portion 11 of the flexible printed board 10 may be directly fixed to the partition plate 260 or may be indirectly fixed via a later-described plate-shaped member 60.

In the present disclosure, the battery pack 200 does not necessarily include the plurality of partition plates 260 as in a later-described fifth embodiment.

Hereinafter, one example of operation upon discharge and charge of the battery unit 300 will be described in more detail.

As described above, upon charge of the battery pack 200, each of the plurality of battery cells 210 expands in the direction apart from the first reference position 510 with reference to the first reference position 510. Along with the expansion of the plurality of battery cells 210, each cell terminal 220 moves in the direction apart from the first reference position 510 in the first direction. Moreover, the connection terminal 55 connected to the cell terminal 220 moves in the direction apart from the corresponding second reference position 520 so as to follow the cell terminal 220. More specifically, each connection terminal 55 of the first flexible printed board 10a and the third flexible printed board 10c moves in the direction (direction indicated by an arrow B in FIG. 2) apart from the second reference position 520a, 520c. Each connection terminal 55 of the second flexible printed board 10b moves in the direction (direction indicated by an arrow C in FIG. 2) apart from the second reference position 520b.

Upon discharge of the battery pack 200, each of the plurality of battery cells 210 contracts rightward with reference to the first reference position 510. Along with the contraction of the plurality of battery cells 210, each cell terminal 220 moves in the direction toward the first reference position 510 in the first direction. The connection terminal 55 connected to the cell terminal 220 moves in the direction toward the corresponding second reference position 520 so as to follow the cell terminal 220. More specifically, each connection terminal 55 of the first flexible printed board 10a and the third flexible printed board 10c moves in the direction toward the second reference position 520a, 520c. Each connection terminal 55 of the second flexible printed board 10b moves in the direction toward the second reference position 520b.

As described above, the connection terminal 55 connected to the cell terminal 220 located farther from the second reference position 520 in the first direction among the plurality of connection terminals 55 has a greater movement amount necessary to follow the cell terminal 220.

In the case of the present embodiment, the voltage monitoring module 100 includes the plurality of flexible printed boards 10 each corresponding to the plurality of sections 250 of the battery pack 200. The connection terminal 55 of the branch portion 20 of the flexible printed board 10 is connected to the cell terminal 220 of the battery cell 210 of the section 250 corresponding to such a flexible printed board 10.

Thus, as compared to a case where one flexible printed board 10 corresponds to the entirety of the battery pack 200, the movement amount necessary for each connection terminal 55 to follow the corresponding cell terminal 220 can be further decreased. Thus, the connection terminal 55 can favorably follow the movement of the corresponding cell terminal 220, and the length dimension of the branch portion 20 and therefore the entirety of the voltage monitoring module 100 can be designed more compact.

As described above, in the case of the present embodiment, the other-section extending portion(s) 13 of one or more of the flexible printed boards 10 (first flexible printed board 10a and third flexible printed board 10c) has the stretchable portion 80.

Thus, by the extension and contraction of the stretchable portion 80, the other-section extending portion 13 can favorably follow the expansion and contraction of the battery cells 210 of the section(s) 250 corresponding to the other flexible printed board(s) 10. Thus, the movement amount necessary for each connection terminal 55 to follow the corresponding cell terminal 220 can be further decreased.

### First Modification of First Embodiment

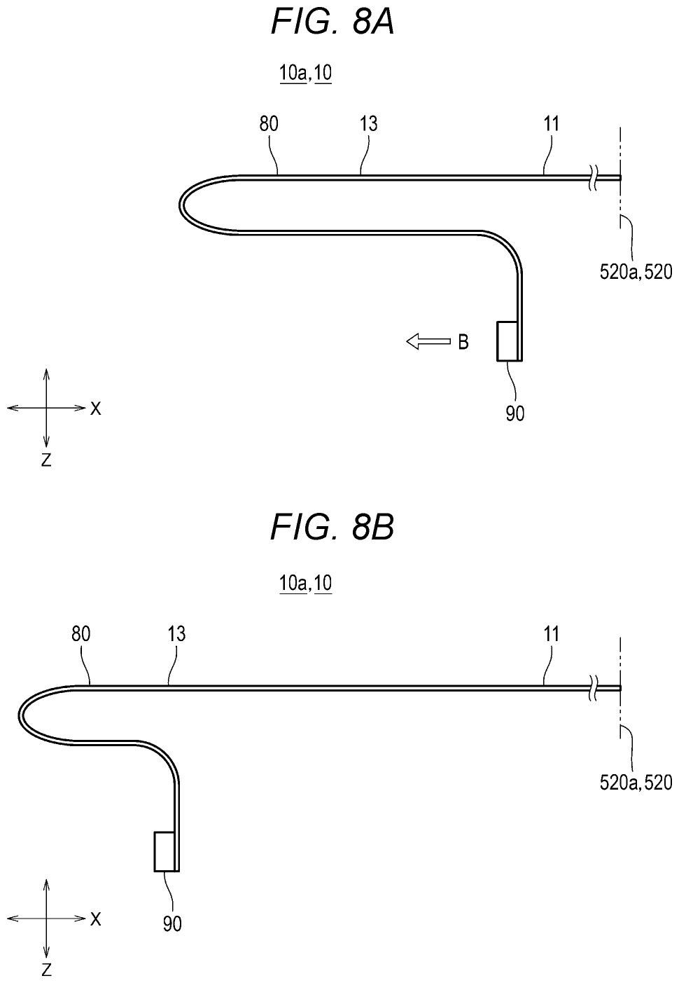

Next, a first modification of the first embodiment will be described with reference to FIGS. 8A and 8B. Note that in FIGS. 8A and 8B, the stretchable portion 80 of the first flexible printed board 10a is shown, but the stretchable portion 80 of the third flexible printed board 10c is not shown.

The voltage monitoring module 100 according to the present modification is different from the voltage monitoring module 100 according to the first embodiment above in the following points, and is similar to the voltage monitoring module 100 according to the first embodiment above in the other points.

As shown in FIGS. 8A and 8B, in the case of the present modification, at the stretchable portion 80, the body portion 11 is folded so as to go back and forth one time in the first direction.

Even with this configuration, by the extension and contraction of the stretchable portion 80, one or more of the flexible printed boards 10 can favorably absorb the expansion and contraction of the battery cells 210 in the section(s) 250 corresponding to the other flexible printed board(s) 10. Thus, the movement amount necessary for each connection terminal 55 to follow the corresponding cell terminal 220 can be further decreased.

More specifically, part of the other-section extending portion 13 is in a shape folded back while being curved from the second reference position 520 side to the side opposite to the second reference position 520 side in the first direction. Flat surfaces of the part of the other-section extending portion 13 face each other in the up-down direction.

Upon charge of the battery pack 200, the folding start point 80a of the stretchable portion 80 moves in the direction (direction indicated by an arrow B in FIG. 8A) apart from the second reference position 520 along with the expansion of the battery cell 210. At this time, the length dimension of the lower portion of the other-section extending portion 13 gradually decreases, and the length dimension of the upper portion gradually increases. Thus, the stretchable portion 80 can extend in the direction apart from the second reference position 520.

Upon discharge of the battery pack 200, the folding start point 80a of the stretchable portion 80 moves in the direction toward the second reference position 520 along with the contraction of the battery cells 210, as shown in FIG. 8B. At this time, the length dimension of the lower portion of the other-section extending portion 13 gradually increases, and the length dimension of the upper portion gradually decreases. Thus, the stretchable portion 80 can contract in the direction toward the second reference position 520.

### Second Modification of First Embodiment

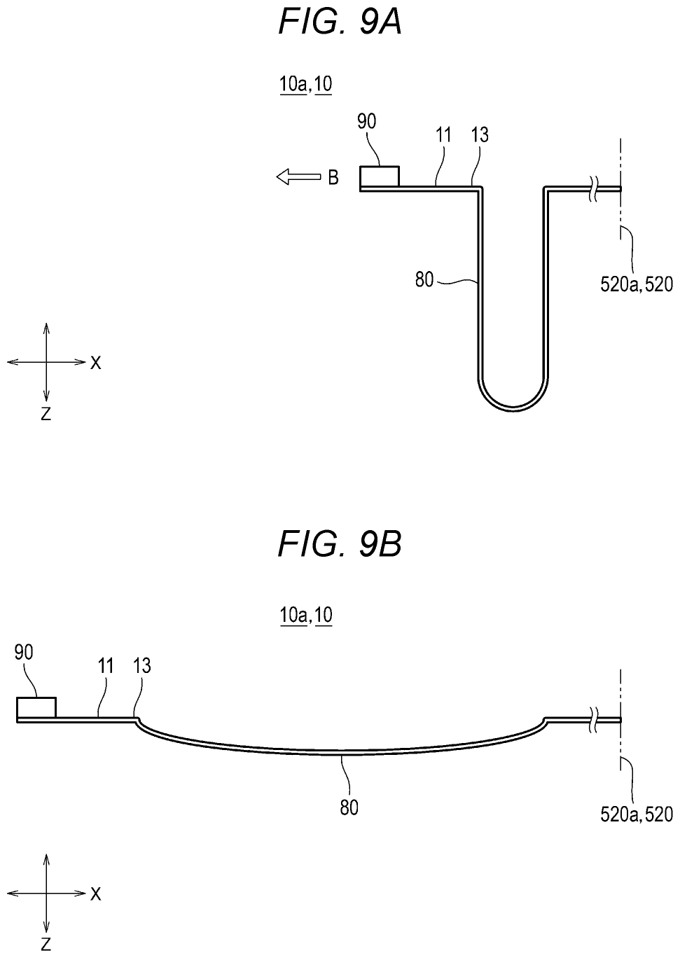

Next, a second modification of the first embodiment will be described with reference to FIGS. 9A and 9B. Note that in FIGS. 9A and 9B, the stretchable portion 80 of the first flexible printed board 10a is shown, but the stretchable portion 80 of the third flexible printed board 10c is not shown.

The voltage monitoring module 100 according to the present modification is different from the voltage monitoring module 100 according to the first embodiment above in the following points, and is similar to the voltage monitoring module 100 according to the first embodiment above in the other points.

As shown in FIGS. 9A and 9B, in the case of the present modification, at the stretchable portion 80, the body portion 11 is curved in the normal direction to other portions of the stretchable portion 80.

Note that the “normal direction to the other portions of the stretchable portion 80” means a normal direction to a portion of the body portion 11 which is not folded back and extends substantially flat. In the example shown in FIGS. 9A and 9B, at the stretchable portion 80, the body portion 11 is curved downward.

Even with this configuration, by the extension and contraction of the stretchable portion 80, one or more of the flexible printed boards 10 can favorably absorb the expansion and contraction of the battery cells 210 in the section(s) 250 corresponding to the other flexible printed board(s) 10. Thus, the movement amount necessary for each connection terminal 55 to follow the corresponding cell terminal 220 can be further decreased.

More specifically, part of the other-section extending portion 13 is curved in a downwardly-raised substantially U-shape, and such a curved portion forms the stretchable portion 80. The stretchable portion 80 is in a substantially U-shape that extends downward and then extends upward so as to return to an original position.

Upon charge of the battery pack 200, the stretchable portion 80 deforms from the substantially U-shaped curved shape to a more flat shape along with the expansion of the battery cells 210. Thus, the stretchable portion 80 can extend in the direction (direction indicated by an arrow B in FIG. 9A) apart from the second reference position 520.

Upon discharge of the battery pack 200, the stretchable portion 80 deforms (returns) from the substantially flat shape to the substantially U-shaped curved shape along with the contraction of the battery cells 210, as shown in FIG. 9A. Thus, the stretchable portion 80 can contract in the direction toward the second reference position 520.

### Third and Fourth Modifications of First Embodiment

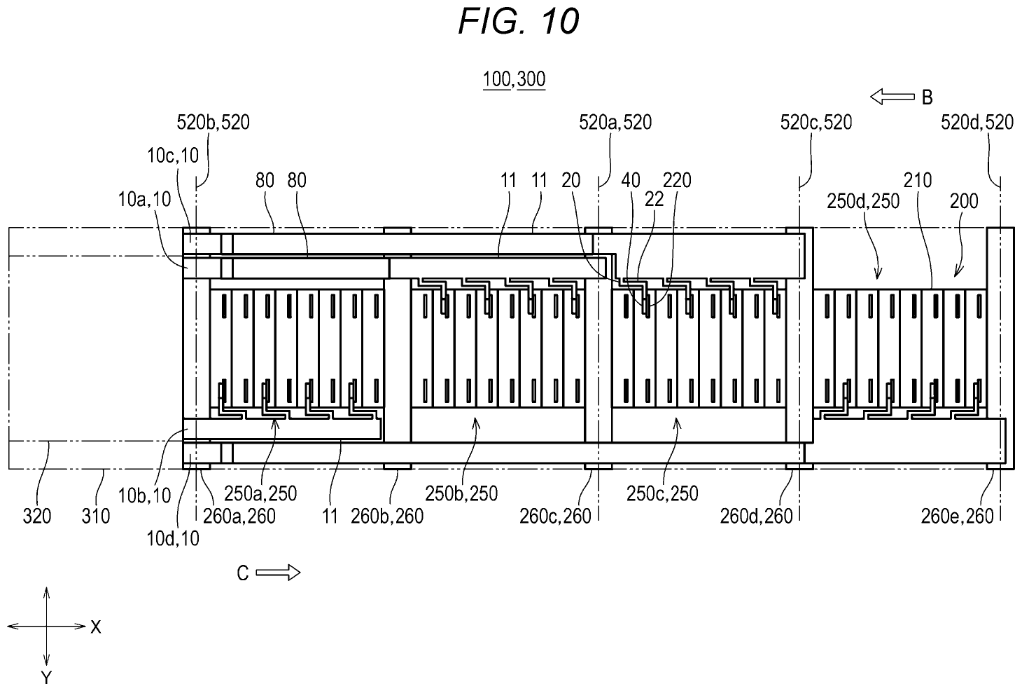

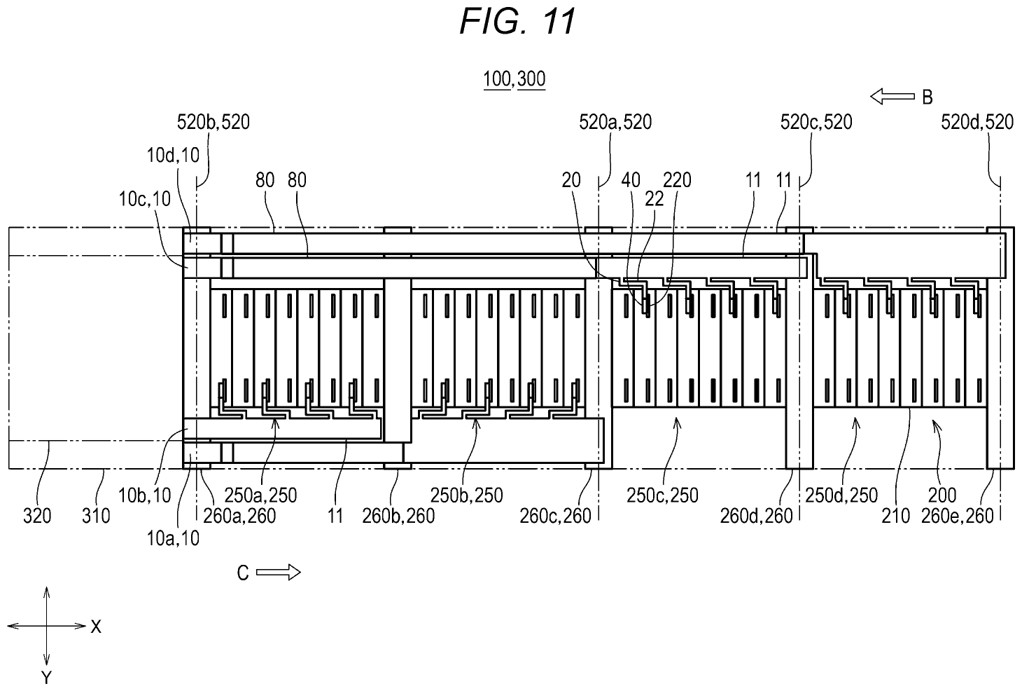

Next, third and fourth modifications of the first embodiment will be described with reference to FIGS. 10 and 11. Note that in FIGS. 10 and 11, the stretchable portion 80 is not shown.

The voltage monitoring modules 100 according to the present modifications are different from the voltage monitoring module 100 according to the first embodiment above in the following points, and are similar to the voltage monitoring module 100 according to the first embodiment above in the other points.

In the present disclosure, the number of sections 250 provided in the battery pack 200 and the number of flexible printed boards 10 provided in the voltage monitoring module 100 are not particularly limited, and can be set as necessary according to the use applications and dimensions of the voltage monitoring module 100 and the battery unit 300.

More specifically, in the examples shown in FIGS. 10 and 11, the battery pack 200 has four sections 250 (first section 250a, second section 250b, third section 250c, and fourth section 250d in this order from the left side), and the voltage monitoring module 100 includes four flexible printed boards 10 (first flexible printed board 10a, second flexible printed board 10b, third flexible printed board 10c, and fourth flexible printed board 10d) each corresponding to these four sections 250. The first flexible printed board 10a corresponds to the second section 250b, the second flexible printed board 10b corresponds to the first section 250a, the third flexible printed board 10c corresponds to the third section 250c, and the fourth flexible printed board 10d corresponds to the fourth section 250d. In the first direction, the second reference position 520b of the second flexible printed board 10b, the second reference position 520a of the first flexible printed board 10a, the second reference position 520c of the third flexible printed board 10c, and the second reference position 520d of the fourth flexible printed board 10d are arranged in this order from the left side.

According to this configuration, for example, even in the battery pack 200 greater in the length dimension as compared to the battery pack 200 of the first embodiment, while the connection terminal 55 is configured to be able to favorably follow the movement of the corresponding cell terminal 220, the length dimension of the branch portion 20 and furthermore the entirety of the voltage monitoring module 100 can be designed more compact.

Note that in the present disclosure, as described above, the flexible printed board 10 disposed on one side in the second direction of the battery pack 200 and the flexible printed board 10 disposed on the other side in the second direction may be replaced with each other.

More specifically, as shown in FIG. 10, for example, with reference to the battery pack 200, the first flexible printed board 10a and the third flexible printed board 10c may be arranged on one side (front side) in the second direction, and the second flexible printed board 10b and the fourth flexible printed board 10d may be arranged on the other side (back side) in the second direction.

As shown in FIG. 11, for example, with reference to the battery pack 200, the second flexible printed board 10b and the first flexible printed board 10a may be arranged on one side (front side) in the second direction, and the fourth flexible printed board 10d and the third flexible printed board 10c may be arranged on the other side (back side) in the second direction.

### Second Embodiment

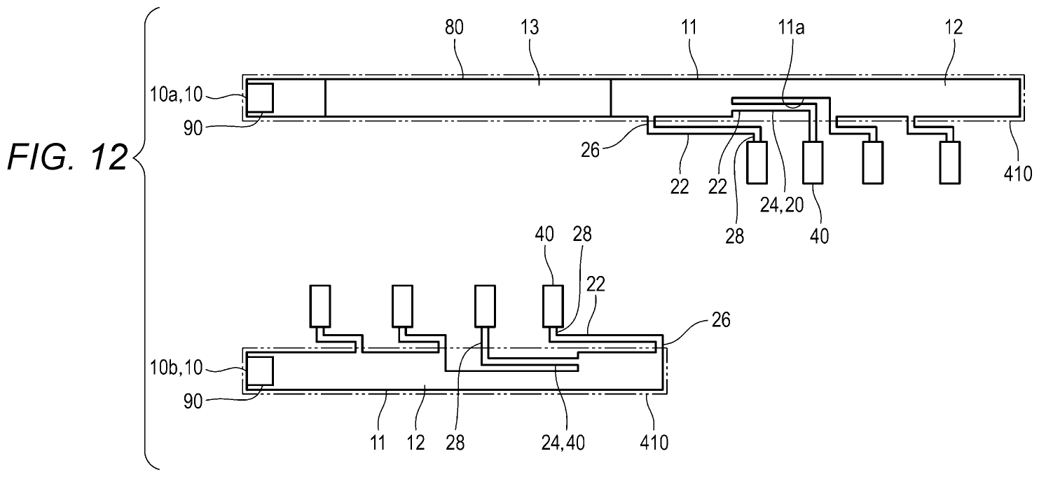

Next, a second embodiment will be described with reference to FIG. 12.

A voltage monitoring module 100 according to the present embodiment is different from the voltage monitoring module 100 according to the first embodiment above in the following points, and is similar to the voltage monitoring module 100 according to the first embodiment above in the other points.

Of the plurality of branch portions 20 of one or more of the flexible printed boards 10, the branch portion 20 located farther from the reference position (second reference position 520) in the first direction preferably has a greater length dimension of the first-direction extending portion 22. In other words, the length dimension of the first-direction extending portion 22 of the branch portion 20 preferably increases as the first-direction extending portion 22 approaches the center of the body portion 11 from both ends (right and left end portions) of the body portion 11 in the first direction.

With this configuration, for the connection terminal 55 connected to one of the plurality of cell terminals 220 located farther from the first reference position 510 in the first direction, the movable range in the direction toward the second reference position 520 and the movable range in the direction apart from the second reference position 520 can be sufficiently ensured. Thus, even in a case where the movement amount of the cell terminal 220 along with the contraction or expansion of the battery cells 210 of the corresponding section 250 is great, the connection terminal 55 can favorably follow the movement of the cell terminal 220.

Note that in the present disclosure, the branch portion 20 located farther from the second reference position 520 in the first direction out of at least two of the plurality of branch portions 20 of one or more of the flexible printed boards 10 is only required to have a greater length dimension of the branch portion 20 from the base end to the connection terminal 55 of the branch portion 20. Preferably, one of the plurality of branch portions 20 located farther from the second reference position 520 in the first direction has a greater length dimension of the branch portion 20 from the base end to the connection terminal 55 of the branch portion 20.

The plurality of branch portions 20 of one or more of the flexible printed boards 10 includes offset branch portions 24 located offset from the other branch portions 20 in the second direction (Y-direction) perpendicular to both the normal direction and first direction of the body portion 11. The offset branch portion 24 is provided at a position different from those of the other branch portions 20 in the second direction. As viewed in the second direction, part of the offset branch portion 24 and part of another branch portion 20 overlap with each other.

In the example shown in FIG. 12, the first-direction extending portion 22 of the offset branch portion 24 of the first flexible printed board 10a is provided on the back side in the second direction with respect to the first-direction extending portions 22 of the other branch portions 20 of the first flexible printed board 10a. Moreover, the first-direction extending portion 22 of the offset branch portion 24 of the second flexible printed board 10b is provided on the front side in the second direction with respect to the first-direction extending portions 22 of the other branch portions 20 of the second flexible printed board 10b.

According to this configuration, even in a case where the movable range of the connection terminal 55 of the offset branch portion 24 and the movable range of each connection terminal 55 of the other branch portions 20 overlap with each other in the first direction, it is possible to suppress mutual interference between the connection terminal 55 of the offset branch portion 24 and each connection terminal 55 of the other branch portions 20 when the connection terminals 55 move so as to follow the cell terminals 220.

Part of some (in the case of the present embodiment, offset branch portion 24) of the plurality of branch portions 20 of one or more of the flexible printed boards 10 is included in a rectangle 410 circumscribed around the body portion 11 in plan view. Note that in FIG. 12, the rectangle 410 is indicated by a dash-dot-dot line.

In the example shown in FIG. 12, the first-direction extending portion 22 and part of the tip end protruding portion 28 of the offset branch portion 24 are included in the rectangle 410 in plan view.

Thus, it is possible to more reliably suppress interference between the connection terminal 55 of the offset branch portion 24 and each connection terminal 55 of the other branch portions 20.

In the case of the present embodiment, the body portion 11 is formed with a slit 11a. In the example shown in FIG. 12, the slit 11a recessed backward is formed in a front edge portion of the body portion 11 of the first flexible printed board 10a and the slit 11a recessed forward is formed in a back edge portion of the body portion 11 of the second flexible printed board 10b. The first-direction extending portions 22 of some branch portions 20 (offset branch portion 24) are arranged inside the slit 11a in plan view. On the other hand, tip end portions of the tip end protruding portions 28 of some branch portions 20 (offset branch portion 24) protrude outward of the slit 11a in plan view.

Note that for making the shape of the rectangle 410 easier to understand, in FIG. 12, each side of the rectangle 410 is shown slightly offset outward with respect to the corresponding side of the body portion 11.

In the example shown in FIG. 12, the branch portion 20 located farther from the second reference position 520 in the first direction out of two of the four branch portions 20 of each of the first flexible printed board 10a and the second flexible printed board 10b has a greater length dimension of the branch portion 20 from the base end to the connection terminal 55 of the branch portion 20.

Moreover, in the example shown in FIG. 12, the plurality of branch portions 20 of each of the first flexible printed board 10a and the second flexible printed board 10b includes the offset branch portion 24. Part of the offset branch portion 24 is included in the rectangle 410 circumscribed around the body portion 11 in plan view.

Note that in FIG. 12, the third flexible printed board 10c of the flexible printed boards 10 is not shown. Note that among the plurality of branch portions 20 of the third flexible printed board 10c, the branch portion 20 located farther from the reference position (second reference position 520) in the first direction may have a greater length dimension of the first-direction extending portion 22. Similarly, the plurality of branch portions 20 of the third flexible printed board 10c may include an offset branch portion 24, and part of some (for example, offset branch portion 24) of the plurality of branch portions 20 of the third flexible printed board 10c may be included in the rectangle 410 circumscribed around the body portion 11 in plan view.

### First and Second Modifications of Second Embodiment

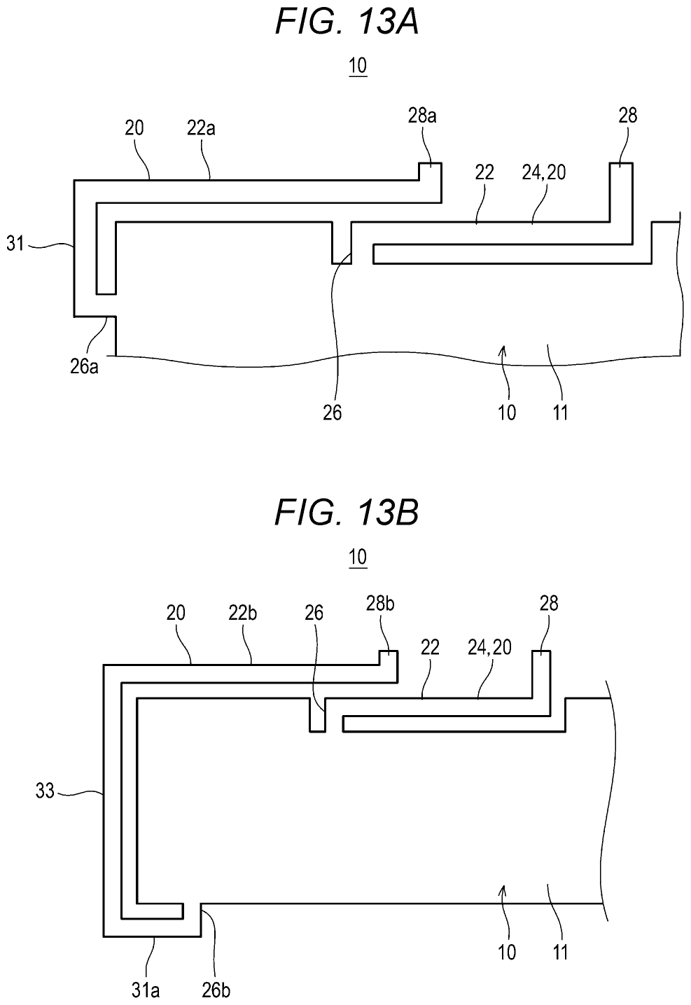

Next, first and second modifications of the second embodiment will be described with reference to FIGS. 13A and 13B.

The voltage monitoring modules 100 according to the present modifications are different from the voltage monitoring module 100 according to the second embodiment above in the following points, and are similar to the voltage monitoring module 100 according to the second embodiment above in the other points.

In the case of the first modification shown in FIG. 13A, the branch portion 20 located on one end side (in the case of the present modification, left end side) in the first direction has a protruding portion 26a protruding in the first direction from one end of the body portion 11 in the first direction, a primary extending portion 31 extending from a tip end portion of the protruding portion 26a in the second direction (in the case of the present modification, backward), a first-direction extending portion 22a extending from a tip end portion of the primary extending portion 31 in the direction opposite to the protruding direction of the protruding portion 26, and a tip end protruding portion 28a protruding in the second direction from a tip end portion of the first-direction extending portion 22a. The tip end protruding portion 28a has the connection terminal 55.

As described above, in the present disclosure, the branch portion 20 may be routed in the same direction as the movement direction of the cell terminal 220 upon the expansion of the battery cells 210. Even with this configuration, the connection terminal 55 can also favorably follow the movement of the cell terminal 220 along with the contraction or expansion of the battery cells 210.

In the case of the second modification shown in FIG. 13B, the branch portion 20 located on one end side (in the case of the present modification, left end side) in the first direction has a protruding portion 26b protruding in the second direction (in the case of the present modification, forward) from the body portion 11, a primary extending portion 31a extending in the first direction from a tip end portion of the protruding portion 26b beyond one end (in the case of the present modification, left end) of the body portion 11 in the first direction, a secondary extending portion 33 extending from a tip end portion of the primary extending portion 31a in the direction (in the case of the present modification, backward) opposite to the protruding direction of the protruding portion 26b beyond the edge (in the case of the present modification, back edge side) of the body portion 11 in the second direction, a first-direction extending portion 22b extending from a tip end portion of the secondary extending portion 33 in the direction opposite to the extending direction of the primary extending portion 31a, and a tip end protruding portion 28b protruding in the direction opposite to the protruding direction of the protruding portion 26b from a tip end portion of the first-direction extending portion 22b. The tip end protruding portion 28b has the connection terminal 55.

As described above, in the present disclosure, the branch portion 20 may be routed so as to bypass one end portion of the body portion 11. Even with this configuration, the connection terminal 55 can also favorably follow the movement of the cell terminal 220 along with the contraction or expansion of the battery cells 210.

Note that the branch portion 20 located on the one end side (in the case of the present modification, left end side) in the first direction as described here means one of the plurality of branch portions 20 located closest to the one end side.

### Third Modification of Second Embodiment

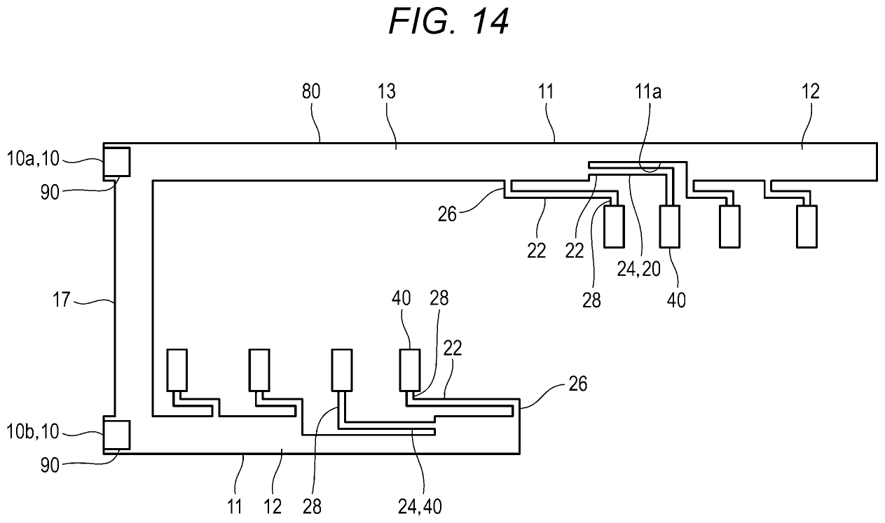

Next, a third modification of the second embodiment will be described with reference to FIG. 14.

The voltage monitoring module 100 according to the present modification is different from the voltage monitoring module 100 according to the second embodiment above in the following points, and is similar to the voltage monitoring module 100 according to the second embodiment above in the other points.

In the case of the present modification, the body portions 11 of the plurality of flexible printed boards 10 are coupled to each other via a coupling portion 17 extending in the second direction.

According to this configuration, the structural strength of the voltage monitoring module 100 can be sufficiently ensured.

Note that the phrase “the body portions 11 of the plurality of flexible printed boards 10 are coupled to each other via the coupling portion 17” means that the body portions 11 of the plurality of flexible printed boards 10 are directly coupled to the coupling portion 17, i.e., these body portions 11 are indirectly coupled to each other via the coupling portion 17. More specifically, the body portions 11 of the plurality of flexible printed boards 10 are integrally formed by punching.

More specifically, as shown in FIG. 14, in the case of the present modification, a left end portion of the first flexible printed board 10a and a left end portion of the second flexible printed board 10b among the plurality of flexible printed boards 10 are coupled to each other via the coupling portion 17.

Note that in FIG. 14, the third flexible printed board 10c is not shown. Note that in the present disclosure, the third flexible printed board 10c may be coupled to the other flexible printed board(s) 10 via the coupling portion 17. More specifically, in the present disclosure, for example, all the flexible printed boards 10 of the voltage monitoring module 100 may be coupled to each other via the coupling portion 17, or some flexible printed boards 10 may be coupled to each other via the coupling portion 17.

### Third Embodiment

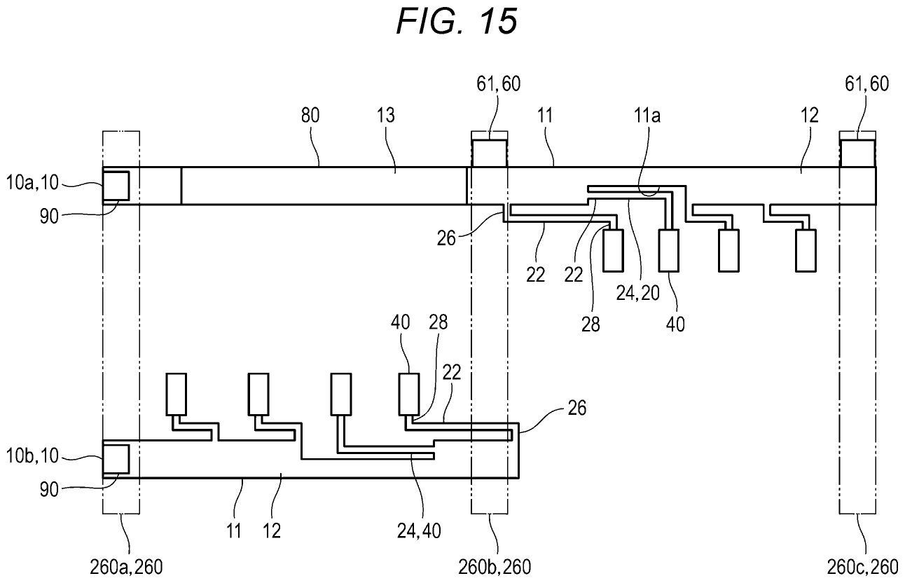

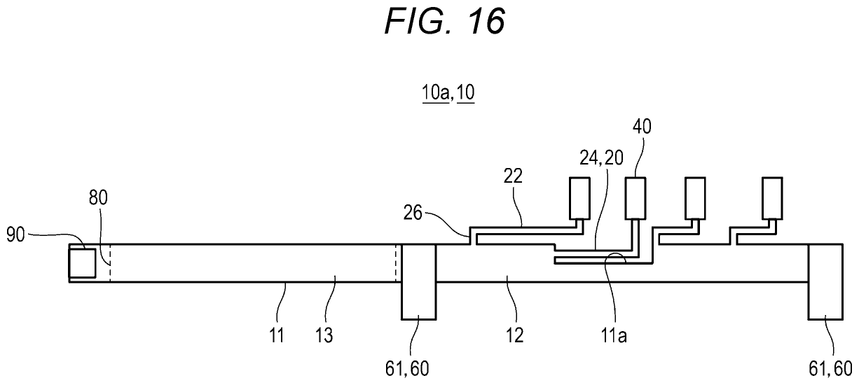

Next, a third embodiment will be described with reference to FIGS. 15 and 16.

A voltage monitoring module 100 according to the present embodiment is different from the voltage monitoring modules 100 according to the first and second embodiments above in the following points, and is similar to the voltage monitoring modules 100 according to the first and second embodiments above in the other points.

In the case of the present embodiment, as shown in FIGS. 15 and 16, the voltage monitoring module 100 includes a rigid plate-shaped member 60 to which the body portion 11 is attached. The plate-shaped member 60 is attached to the body portion 11 of at least one of the flexible printed boards 10. According to this configuration, the structural strength of the body portion 11 can be sufficiently ensured.

More specifically, in the case of the present embodiment, an end portion(s) of the body portion(s) 11 of one or more of the flexible printed boards 10 on the side on which the corresponding-section extending portion 12 is provided and a portion of the body portion 11 of such a flexible printed board 10 between the corresponding-section extending portion 12 and the stretchable portion 80 are indirectly fixed to the battery cells 210 via the rigid plate-shaped members 60.

According to this configuration, one or more of the flexible printed boards 10 can be more reliably configured such that the stretchable portion 80 of the other-section extending portion 13 absorbs the expansion and contraction of the battery cells 210 of the section(s) 250 corresponding to the other flexible printed board(s) 10 and the plurality of branch portions 20 formed at the corresponding-section extending portion 12 absorbs the change in the positions of the cell terminals 220 of the corresponding section 250.

More specifically, in the case of the present embodiment, the voltage monitoring module 100 has, as the plate-shaped member 60, a pair of first reinforcing plates 61.

A material forming the pair of first reinforcing plates 61 is not particularly limited, and one example thereof may include a hard resin material.

Each of the pair of first reinforcing plates 61 is formed in a rectangular shape long in the second direction in plan view. Each of the pair of first reinforcing plates 61 is attached along the lower surface (battery pack 200-side surface) of the body portion 11. A back end portion of each of the pair of first reinforcing plates 61 projects backward from the body portion 11 in plan view, for example.

One of the pair of first reinforcing plates 61 is attached to an end portion (in the case of the present embodiment, right end portion) of the body portion 11 of the flexible printed board 10 on the side on which the corresponding-section extending portion 12 is provided, and such an end portion is fixed to the partition plate 260 (and therefore the battery cell 210) via the one of the first reinforcing plates 61. The other first reinforcing plate 61 is attached to a portion (in the case of the present embodiment, intermediate portion) of the body portion 11 of the flexible printed board 10 between the corresponding-section extending portion 12 and the stretchable portion 80, and such an intermediate portion is fixed to the partition plate 260 (and therefore the battery cell 210) via the other first reinforcing plate 61. Note that in FIG. 15, the partition plate 260 is indicated by a dash-dot-dot line.

Note that in the present disclosure, the pair of first reinforcing plates 61 may be directly fixed to the corresponding battery cells 210.

Note that a method for fixing the pair of first reinforcing plates 61 to the body portion 11 of the flexible printed board 10 is not particularly limited and the pair of first reinforcing plates 61 may be fixed, for example, by thermal swaging or using an adhesive.

FIGS. 15 and 16 show an example where the first flexible printed board 10a is attached to the plate-shaped members 60 (the pair of first reinforcing plates 61), but the other flexible printed boards 10 may be attached to the plate-shaped members 60 (the pair of first reinforcing plates 61). More specifically, in the present disclosure, for example, all the flexible printed boards 10 of the voltage monitoring module 100 may be attached to the plate-shaped members 60 (the pair of first reinforcing plates 61), or some flexible printed boards 10 may be attached to the plate-shaped members 60 (the pair of first reinforcing plates 61).

### First Modification of Third Embodiment

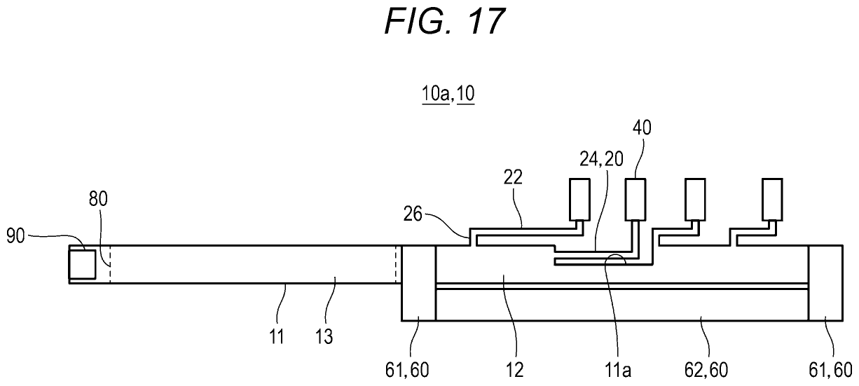

Next, a first modification of the third embodiment will be described with reference to FIG. 17.

The voltage monitoring module 100 according to the present modification is different from the voltage monitoring module 100 according to the third embodiment above in the following points, and is similar to the voltage monitoring module 100 according to the third embodiment above in the other points.

In the case of the present modification, in addition to the pair of first reinforcing plates 61 as the plate-shaped member 60, the voltage monitoring module 100 may further include a coupling plate 62 coupling the pair of first reinforcing plates 61 to each other.

According to this configuration, for example, one or more of the flexible printed boards 10 can be more reliably configured, for example, without fixing the body portions 11 to the battery pack 200 via the plate-shaped members 60 (more specifically, the pair of first reinforcing plates 61) such that the stretchable portion 80 of the other-section extending portion 13 absorbs the expansion and contraction of the battery cells 210 of the section(s) 250 corresponding to the other flexible printed board(s) 10 and the plurality of branch portions 20 formed at the corresponding-section extending portion 12 absorbs the change in the positions of the cell terminals 220 of the corresponding section 250.

More specifically, the coupling plate 62 extends, for example, linearly in the first direction, and is bridged between one of the first reinforcing plates 61 and the other first reinforcing plate 61.

### Second Modification of Third Embodiment

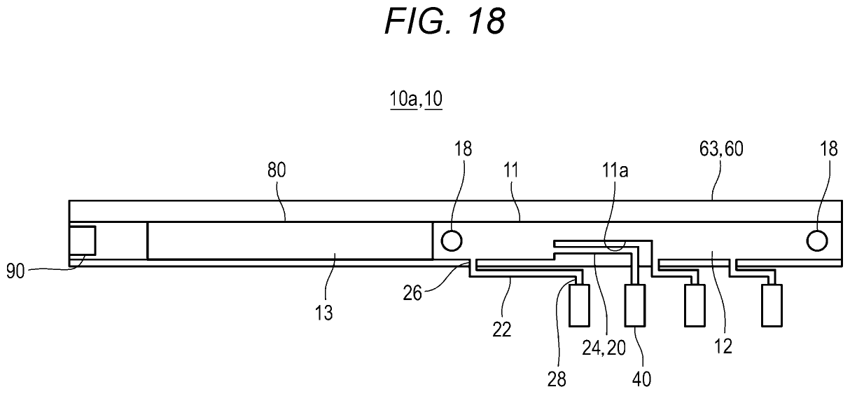

Next, a second modification of the third embodiment will be described with reference to FIG. 18.

The voltage monitoring module 100 according to the present modification is different from the voltage monitoring modules 100 according to the third embodiment and the first modification thereof above in the following points, and is similar to the voltage monitoring modules 100 according to the third embodiment and the first modification thereof above in the other points.

In the case of the present modification, as shown in FIG. 18, the voltage monitoring module 100 includes, as the plate-shaped member 60, one second reinforcing plate 63 extending linearly in the first direction.

According to this configuration, the structural strength of the body portion 11 can be sufficiently ensured.

More specifically, the second reinforcing plate 63 extends over the entirety of the flexible printed board 10 in the longitudinal direction thereof, and the entirety of the body portion 11 of the flexible printed board 10 is disposed on the upper surface of the second reinforcing plate 63.

A material forming the second reinforcing plate 63 is not particularly limited, and one example thereof may include a hard resin material.

In the example shown in FIG. 18, an end portion (in the case of the present modification, right end portion) of the body portion 11 of the flexible printed board 10 on the side on which the corresponding-section extending portion 12 is provided is fixed to the second reinforcing plate 63 by thermal swaging. Similarly, a portion (in the case of the present modification, intermediate portion) of the body portion 11 of the flexible printed board 10 between the corresponding-section extending portion 12 and the stretchable portion 80 is fixed to the second reinforcing plate 63 by thermal swaging.

More specifically, as one example, a thermal swaging portion 18 is formed at each of the right end portion and intermediate portion of the body portion 11, and the body portion 11 is fixed to the plate-shaped member 60 (second reinforcing plate 63) by the thermal swaging portions 18. A protruding portion (not shown) is formed on the upper surface of the second reinforcing plate 63, and a through-hole (not shown) is formed in a portion of the body portion 11 corresponding to the protruding portion. In a state of the protruding portion of the second reinforcing plate 63 being inserted into the through-hole of the body portion 11, a tip end portion of the protruding portion is crushed by thermal swaging such that the outer diameter thereof increases as compared to the inner diameter of the through-hole. In this manner, the thermal swaging portion 18 is formed, and the protruding portion of the plate-shaped member 60 is retained in the body portion 11.

Note that FIG. 18 shows an example where the first flexible printed board 10a is attached to the plate-shaped member 60 (second reinforcing plate 63), but the other flexible printed boards 10 may be attached to the plate-shaped members 60 (second reinforcing plates 63). More specifically, in the present disclosure, for example, all the flexible printed boards 10 of the voltage monitoring module 100 may be attached to the plate-shaped members 60 (second reinforcing plates 63), or some flexible printed boards 10 may be attached to the plate-shaped members 60 (second reinforcing plates 63).

### Fourth Embodiment

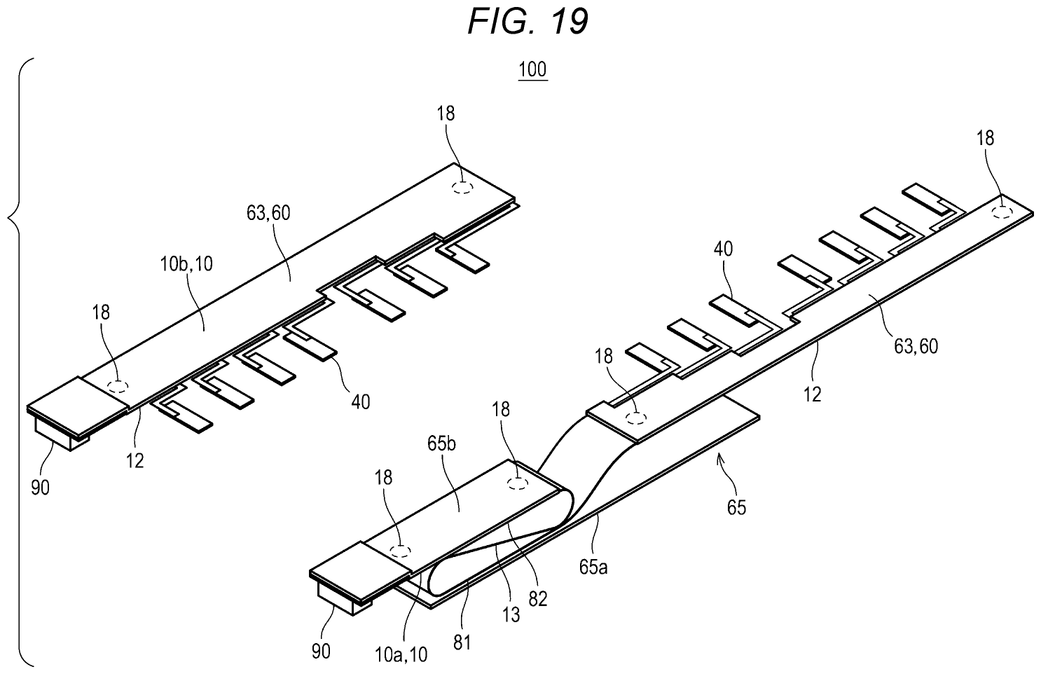

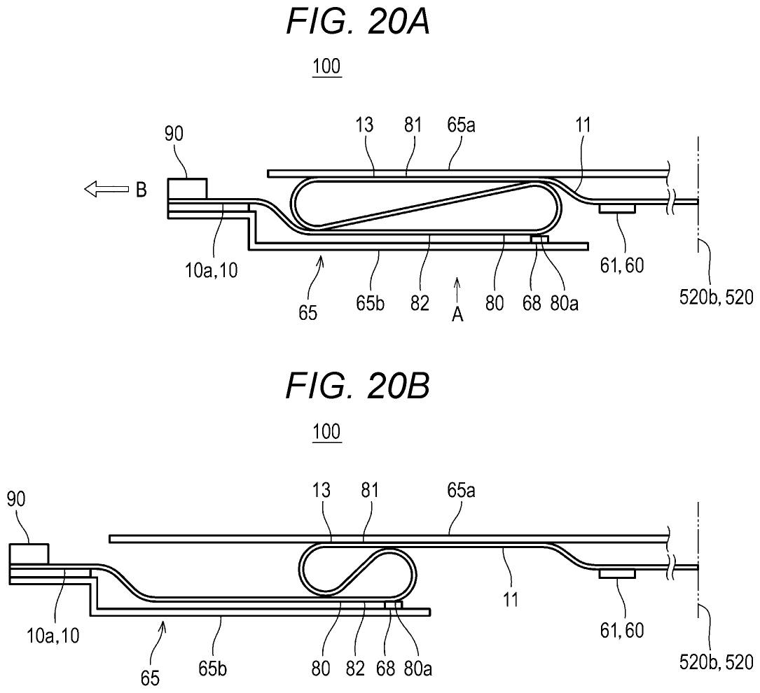

Next, a fourth embodiment will be described with reference to FIGS. 19, 20A, and 20B. Note that FIG. 19 is a perspective view showing a voltage monitoring module 100 from the bottom side.

The voltage monitoring module 100 according to the present embodiment is different from the voltage monitoring modules 100 according to the first to third embodiments above in the following points, and is similar to the voltage monitoring modules 100 according to the first to third embodiments above in the other points.

In the case of the present embodiment, the case 65 that houses the stretchable portion(s) 80 of one or more of the flexible printed boards 10 is provided, and the case 65 restricts bulging of the stretchable portion 80 in the normal direction to the other portions of the stretchable portion 80 of the body portion 11.

Note that the “normal direction to the other portions of the stretchable portion 80” means a normal direction to a portion of the body portion 11 which is not folded back and extends substantially flat.

Moreover, the phrase “restricts bulging” means that the stretchable portion 80 is restrained in a folded shape.

According to this configuration, the stretchable portion 80 can extend and contract along with the expansion and contraction of the battery cells 210 while favorably maintaining the shape folded back in the first direction.

Further, in the case of the present embodiment, the folding start point 80a of the stretchable portion 80 is fixed to the case 65.

According to this configuration, the stretchable portion 80 can extend and contract with reference to the folding start point 80a with favorable reproducibility.

Note that as described above, in the present disclosure, the “folding start point 80a” means the standing start position of the other-section extending portion 13 from the extending flat state.

More specifically, the case 65 includes, for example, a top surface portion 65a disposed along an upper side flat surface of the stretchable portion 80, a bottom surface portion 65b disposed along a lower side flat surface of the stretchable portion 80, and a pair of side portions (not shown) covering the sides of the stretchable portion 80 and coupling the top surface portion 65a and the bottom surface portion 65b to each other.

According to this configuration, the top surface portion 65a can restrict upward bulging of the stretchable portion 80, and the bottom surface portion 65b can restrict downward bulging of the stretchable portion 80. Moreover, the pair of side portions can also restrict lateral bulging of the stretchable portion 80. That is, the case 65 is configured to restrict the upward, downward, and lateral bulging of the stretchable portion 80.

Each of the top surface portion 65a and the bottom surface portion 65b is formed in a flat plate shape, and extends linearly in the first direction. Note that part of a left end portion of the bottom surface portion 65b forms a step portion, for example. Note that the part of the left end portion of the bottom surface portion 65b does not necessarily form the step portion.

As shown in FIG. 19, the case 65 is fixed to the stretchable portion 80 by the thermal swaging portions 18, for example.

More specifically, a portion of the other-section extending portion 13 on the left side of the folding start point 80a of the stretchable portion 80 in the vicinity of the folding start point 80a is fixed to the bottom surface portion 65b via the thermal swaging portion 18. Moreover, a portion of the other-section extending portion 13 on the left side of a folding end point of the stretchable portion 80 in the vicinity of the folding end point is fixed to the bottom surface portion 65b via the thermal swaging portion 18.

Note that in FIGS. 20A and 20B, the thermal swaging portion 18 is not shown.

A material forming the case 65 is not particularly limited, and one example thereof may include a hard resin material.

In the case of the present embodiment, as shown in FIG. 19, the above-described second reinforcing plate 63 may be fixed to a portion of each flexible printed board 10 exposed from the case 65.

According to this configuration, while the shape of the stretchable portion 80 can be favorably held by the case 65, the structural strength of each flexible printed board 10 is favorably ensured.

As shown in FIGS. 20A and 20B, in the case of the present embodiment, the folding start point 80a of the stretchable portion 80 is fixed to the upper surface of the bottom surface portion 65b via an adhesive sheet 68.

Note that in the present disclosure, a method for fixing the folding start point 80a of the stretchable portion 80 to the case 65 is not limited to this example and other methods such as an adhesive or swaging fixing can be used as necessary.

Moreover, in the present disclosure, the folding start point 80a of the stretchable portion 80 is not necessarily fixed to the case 65, for example.

Note that FIGS. 19, 20A, and 20B shows an example where the stretchable portion 80 of the first flexible printed board 10a is housed in the case 65, but the stretchable portions 80 of the other flexible printed boards 10 may be housed in the cases 65. More specifically, in the present disclosure, the stretchable portions 80 of all the flexible printed boards 10 of the voltage monitoring module 100 may be housed in the cases 65, or the stretchable portions 80 of some flexible printed boards 10 may be housed in the cases 65.

### Fifth Embodiment

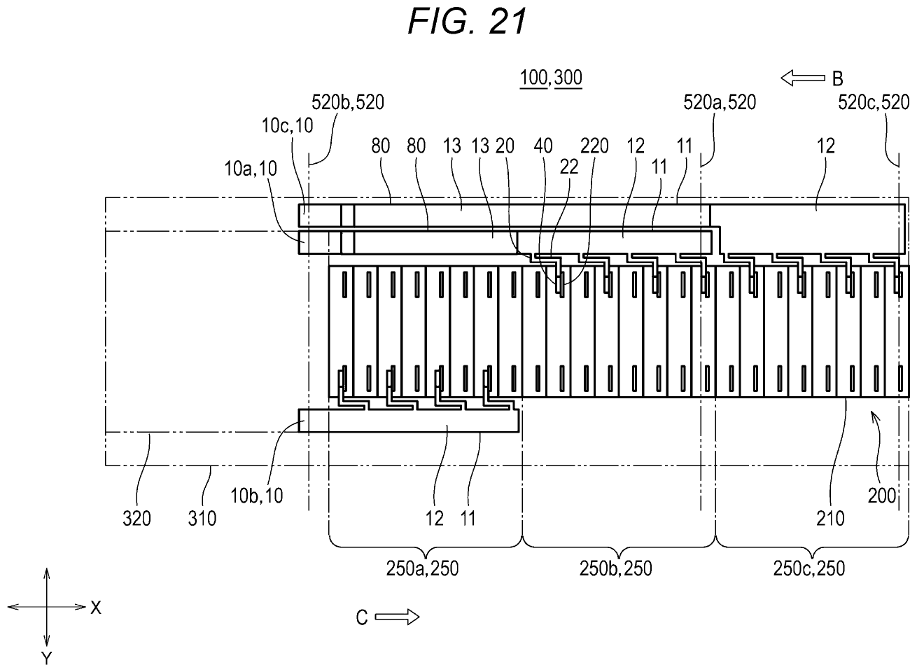

Next, a fifth embodiment will be described with reference to FIG. 21.

A voltage monitoring module 100 according to the present embodiment is different from the voltage monitoring modules 100 according to the first to fourth embodiments above in the following points, and is similar to the voltage monitoring modules 100 according to the first to fourth embodiments above in the other points.

As shown in FIG. 21, in the case of the present embodiment, the voltage monitoring module 100 does not include the plurality of partition plates 260, and over the entirety of the battery pack 200, the plate surfaces of adjacent ones of the battery cells 210 are arranged in surface contact with each other.

The body portion 11 of each flexible printed board 10 is directly or indirectly (e.g., via the above-described plate-shaped member 60) fixed to the corresponding battery cells 210.

More specifically, the first reference position 510-side end portion (in the case of the present embodiment, right end portion) of the body portion 11 of the first flexible printed board 10a is directly or indirectly fixed to the battery cell 210 located closest to the first reference position 510 side among the battery cells 210 of the second section 250b. In the first direction, the second reference position 520a of the first flexible printed board 10a is located at the same position as or in the vicinity of the battery cell 210 located closest to the first reference position 510 side among the battery cells 210 of the second section 250b.

On the other hand, an end portion (in the case of the present embodiment, left end portion) of the body portion 11 of the first flexible printed board 10a opposite to the first reference position 510 side is movable in the directions apart from and toward the first reference position 510 so as to follow the expansion and contraction of the battery pack 200. More specifically, the left end portion of the body portion 11 of the first flexible printed board 10a is directly or indirectly (e.g., via the above-described plate-shaped member 60 or buffer 320) fixed to the battery cell 210 located farthest from the first reference position 510 among all the battery cells 210 of the battery pack 200, for example.

Similarly, the first reference position 510-side end portion (in the case of the present embodiment, right end portion) of the body portion 11 of the third flexible printed board 10c is directly or indirectly fixed to the battery cell 210 located closest to the first reference position 510 side among the battery cells 210 of the third section 250c. In the first direction, the second reference position 520c of the third flexible printed board 10c is located at the same position as or in the vicinity of the battery cell 210 located closest to the first reference position 510 side among the battery cells 210 of the third section 250c.

On the other hand, the end portion (in the case of the present embodiment, left end portion) of the body portion 11 of the third flexible printed board 10c opposite to the first reference position 510 side is movable in the directions apart from and toward the first reference position 510 so as to follow the expansion and contraction of the battery pack 200. More specifically, the left end portion of the body portion 11 of the third flexible printed board 10c is directly or indirectly fixed to the battery cell 210 located farthest from the first reference position 510 among all the battery cells 210 of the battery pack 200, for example.

The first reference position 510-side end portion (in the case of the present embodiment, right end portion) of the body portion 11 of the second flexible printed board 10b is not fixed to the battery pack 200.

On the other hand, the end portion (in the case of the present embodiment, left end portion) of the body portion 11 of the second flexible printed board 10b opposite to the first reference position 510 side is movable in the directions apart from and toward the first reference position 510 so as to follow the expansion and contraction of the battery pack 200. More specifically, the left end portion of the body portion 11 of the second flexible printed board 10b is directly or indirectly fixed to the battery cell 210 located farthest from the first reference position 510 among all the battery cells 210 of the battery pack 200, for example.

In the first direction, the second reference position 520b of the second flexible printed board 10b is located at the same position as or in the vicinity of the battery cell 210 located farthest from the first reference position 510.

Each embodiment has been described above with reference to the drawings, but these embodiments are examples of the present disclosure and various configurations other than those described above can also be employed.

For example, the example where the cell terminal 220 is formed in the flat plate shape has been described above, but in the present disclosure, the shape of the cell terminal 220 is not limited to that of this example and may be, for example, a circular columnar shape.

In the present disclosure, the first reference position 510 in the expansion and contraction of the battery cells 210 is not limited to one end position in the first direction, for example, may be the center position of the battery pack 200.

The present embodiments include the following technical ideas.

(1) A voltage monitoring module for monitoring a voltage of a battery pack configured such that a plurality of sections, each of which includes a plurality of battery cells arranged in a first direction, is arranged in the first direction, including:
a plurality of flexible printed boards,
in which each of the plurality of flexible printed boards has a body portion and a plurality of branch portions,
the body portion extends in the first direction,
each of the plurality of branch portions is branched from the body portion, and is arranged at intervals in the first direction,
each of the plurality of branch portions is provided with a connection terminal on a tip end side, and
the plurality of flexible printed boards is each arranged corresponding to each of the plurality of sections, and the connection terminal is connected to a corresponding one of terminals of the plurality of battery cells of the section corresponding to the flexible printed board.

(2) The voltage monitoring module according to (1), in which the body portion of one or more of the flexible printed boards has a first extending portion and a second extending portion,
the plurality of branch portions is branched from the first extending portion of the body portion,
the first extending portion extends along the section corresponding to one of the plurality of flexible printed boards, and
the second extending portion extends along the section corresponding to the flexible printed board other than the one of the plurality of flexible printed boards.

(3) The voltage monitoring module according to (2), in which a length dimension of the first extending portion in a second direction perpendicular to both a normal direction and the first direction of the body portion is greater than a length dimension of the second extending portion in the second direction.

(4) The voltage monitoring module according to any one of (1) to (3), in which each of the plurality of branch portions includes a first-direction extending portion extending in the first direction, and
a length dimension of the first-direction extending portion of each of the plurality of branch portions of one or more of the flexible printed boards increases as the first-direction extending portion approaches a center of the body portion from both ends of the body portion in the first direction.

(5) The voltage monitoring module according to any one of (1) to (4), in which the plurality of branch portions includes an offset branch portion, and the offset branch portion is provided at a position different from a position of the branch portion other than the offset branch portion in a second direction perpendicular to both a normal direction and the first direction of the body portion, and as viewed in the second direction, part of the offset branch portion and part of the branch portion other than the offset branch portion overlap with each other.

(6) The voltage monitoring module according to any one of (1) to (5), in which part of some of the plurality of branch portions is included in a rectangle circumscribed around the body portion in plan view.

(7) The voltage monitoring module according to any one of (1) to (6), further including:
a plate-shaped member,
in which the plate-shaped member is attached to the body portion of at least one of the flexible printed boards.

(8) The voltage monitoring module according to any one of (1) to (7), in which
the body portions of the plurality of flexible printed boards are separated from each other.

(9) The voltage monitoring module according to any one of (1) to (8), further including:
a coupling portion,
in which the coupling portion extends in a second direction perpendicular to both a normal direction and the first direction of the body portion, and
the body portions of the plurality of flexible printed boards are coupled to each other via the coupling portion.

(10) The voltage monitoring module according to any one of (2) to (9), in which the second extending portion has a stretchable portion extendable and contractable in the first direction.

(11) The voltage monitoring module according to (10), in which at the stretchable portion, parts of the body portion overlap with each other by the body portion being folded back.

(12) The voltage monitoring module according to (11), in which at the stretchable portion, part of the body portion is folded so as to go back and forth one and a half times or more in the first direction, and the part of the body portion meanders in a normal direction of the body portion.

(13) The voltage monitoring module according to (10), in which at the stretchable portion, the body portion is curved downward.

(14) The voltage monitoring module according to (12), further including:
a case that houses the stretchable portion,
in which the case restricts upward and downward bulging of the stretchable portion.

(15) The voltage monitoring module according to (14), in which a folding start point of the stretchable portion is fixed to the case.

(16) A battery unit including:
a battery pack; and
a voltage monitoring module that monitors a voltage of the battery pack,
in which the battery pack has a plurality of sections arranged in a first direction, and each of the plurality of sections has a plurality of battery cells arranged in the first direction,
the voltage monitoring module has a plurality of flexible printed boards,
in which each of the plurality of flexible printed boards has a body portion and a plurality of branch portions,
the body portion extends in the first direction,
each of the plurality of branch portions is branched from the body portion, and is arranged at intervals in the first direction,
each of the plurality of branch portions is provided with a connection terminal on a tip end side, and
the plurality of flexible printed boards is each arranged corresponding to each of the plurality of sections, and the connection terminal is connected to a corresponding one of terminals of the plurality of battery cells of the section corresponding to the flexible printed board.

(17) The battery unit according to (16), in which
the body portion of one or more of the flexible printed boards has a first extending portion and a second extending portion,
the plurality of branch portions is branched from the first extending portion of the body portion,
the first extending portion extends along the section corresponding to one of the plurality of flexible printed boards, and
the second extending portion extends along the section corresponding to the flexible printed board other than the one of the plurality of flexible printed boards.

(18) The battery unit according to (17), in which the second extending portion has a stretchable portion extendable and contractable in the first direction.

(19) The battery unit according to (18), in which the voltage monitoring module further has a plurality of plate-shaped members, and
an end portion of the body portion of one or more of the flexible printed boards on a side on which the first extending portion is provided and a portion of the body portion of the one or more of the flexible printed boards between the first extending portion and the stretchable portion are fixed to the battery cells via the plate-shaped members.

(20) The battery unit according to any one of (16) to (19), further including:
a plurality of partition plates,
in which the plurality of partition plates partitions the battery pack into the plurality of sections.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A voltage monitoring module for monitoring a voltage of a battery pack configured such that a plurality of sections, each of which includes a plurality of battery cells arranged in a first direction, is arranged in the first direction, comprising:
a plurality of flexible printed boards,
wherein each of the plurality of flexible printed boards has a body portion and a plurality of branch portions,
the body portion extends in the first direction,
each of the plurality of branch portions is branched from the body portion, and is arranged at intervals in the first direction,
each of the plurality of branch portions is provided with a connection terminal on a tip end side, and
the plurality of flexible printed boards is each arranged corresponding to each of the plurality of sections, and the connection terminal is connected to a corresponding one of terminals of the plurality of battery cells of the section corresponding to the flexible printed board.

2. The voltage monitoring module according to claim 1, wherein
the body portion of one or more of the flexible printed boards has a first extending portion and a second extending portion,
the plurality of branch portions is branched from the first extending portion of the body portion,
the first extending portion extends along the section corresponding to one of the plurality of flexible printed boards, and
the second extending portion extends along the section corresponding to the flexible printed board other than the one of the plurality of flexible printed boards.

3. The voltage monitoring module according to claim 2, wherein
a length dimension of the first extending portion in a second direction perpendicular to both a normal direction and the first direction of the body portion is greater than a length dimension of the second extending portion in the second direction.

4. The voltage monitoring module according to claim 1, wherein
each of the plurality of branch portions includes a first-direction extending portion extending in the first direction, and
a length dimension of the first-direction extending portion of each of the plurality of branch portions of one or more of the flexible printed boards increases as the first-direction extending portion approaches a center of the body portion from both ends of the body portion in the first direction.

5. The voltage monitoring module according to claim 1, wherein
the plurality of branch portions includes an offset branch portion, and
the offset branch portion is provided at a position different from a position of the branch portion other than the offset branch portion in a second direction perpendicular to both a normal direction and the first direction of the body portion, and as viewed in the second direction, part of the offset branch portion and part of the branch portion other than the offset branch portion overlap with each other.

6. The voltage monitoring module according to claim 1, wherein
part of some of the plurality of branch portions is included in a rectangle circumscribed around the body portion in plan view.

7. The voltage monitoring module according to claim 1, further comprising:
a plate-shaped member,
wherein the plate-shaped member is attached to the body portion of at least one of the flexible printed boards.

8. The voltage monitoring module according to claim 1, wherein
the body portions of the plurality of flexible printed boards are separated from each other.

9. The voltage monitoring module according to claim 1, further comprising:
a coupling portion,
wherein the coupling portion extends in a second direction perpendicular to both a normal direction and the first direction of the body portion, and
the body portions of the plurality of flexible printed boards are coupled to each other via the coupling portion.

10. The voltage monitoring module according to claim 2, wherein
the second extending portion has a stretchable portion extendable and contractable in the first direction.

11. The voltage monitoring module according to claim 10, wherein
at the stretchable portion, parts of the body portion overlap with each other by the body portion being folded back.

12. The voltage monitoring module according to claim 11, wherein
at the stretchable portion, part of the body portion is folded so as to go back and forth one and a half times or more in the first direction, and the part of the body portion meanders in a normal direction of the body portion.

13. The voltage monitoring module according to claim 10, wherein
at the stretchable portion, the body portion is curved downward.

14. The voltage monitoring module according to claim 12, further comprising:
a case that houses the stretchable portion,
wherein the case restricts upward and downward bulging of the stretchable portion.

15. The voltage monitoring module according to claim 14, wherein
a folding start point of the stretchable portion is fixed to the case.

16. A battery unit comprising:
a battery pack; and
a voltage monitoring module that monitors a voltage of the battery pack,
wherein the battery pack has a plurality of sections arranged in a first direction, and each of the plurality of sections has a plurality of battery cells arranged in the first direction,
the voltage monitoring module has a plurality of flexible printed boards,
wherein each of the plurality of flexible printed boards has a body portion and a plurality of branch portions,
the body portion extends in the first direction,
each of the plurality of branch portions is branched from the body portion, and is arranged at intervals in the first direction,
each of the plurality of branch portions is provided with a connection terminal on a tip end side, and
the plurality of flexible printed boards is each arranged corresponding to each of the plurality of sections, and the connection terminal is connected to a corresponding one of terminals of the plurality of battery cells of the section corresponding to the flexible printed board.

17. The battery unit according to claim 16, wherein
the body portion of one or more of the flexible printed boards has a first extending portion and a second extending portion,
the plurality of branch portions is branched from the first extending portion of the body portion,
the first extending portion extends along the section corresponding to one of the plurality of flexible printed boards, and
the second extending portion extends along the section corresponding to the flexible printed board other than the one of the plurality of flexible printed boards.

18. The battery unit according to claim 17, wherein
the second extending portion has a stretchable portion extendable and contractable in the first direction.

19. The battery unit according to claim 18, wherein
the voltage monitoring module further has a plurality of plate-shaped members, and
an end portion of the body portion of one or more of the flexible printed boards on a side on which the first extending portion is provided and a portion of the body portion of the one or more of the flexible printed boards between the first extending portion and the stretchable portion are fixed to the battery cells via the plate-shaped members.

20. The battery unit according to claim 16, further comprising:
a plurality of partition plates,
wherein the plurality of partition plates partitions the battery pack into the plurality of sections.
